(19) United States
(12) Patent Application Publication
(10) Pub. No.: US 2025/0142915 A1
(43) Pub. Date: May 1, 2025

(54) GROUP III-NITRIDE HIGH-ELECTRON MOBILITY TRANSISTORS CONFIGURED WITH A LOW RESISTANCE CONTACT LAYER FOR SOURCE AND/OR DRAIN CONTACTS AND PROCESS FOR IMPLEMENTING THE SAME

(71) Applicant: WOLFSPEED, INC., Durham, NC (US)

(72) Inventors: Matthew KING, Wake Forest, NC (US); James TWEEDIE, Raleigh, NC (US); Kyle BOTHE, Cary, NC (US); Scott SHEPPARD, Chapel Hill, NC (US)

(21) Appl. No.: 18/383,733

(22) Filed: Oct. 25, 2023

(51) Int. Cl. H01L 29/45; H01L 21/285; H01L 29/20; H01L 29/40; H01L 29/66; H01L 29/778

(52) U.S. Cl. CPC H10D 62/85; H01L 21/28575; H10D 30/015; H10D 30/475; H10D 62/8503; H10D 64/111; H10D 64/62

(57) ABSTRACT

A transistor includes a group III-Nitride channel layer; a group III-Nitride barrier layer on the group III-Nitride channel layer, the group III-Nitride barrier layer having a higher bandgap than a bandgap of the group III-Nitride channel layer; a low resistance contact layer on the group III-Nitride barrier layer and/or on the group III-Nitride channel layer; a source electrically coupled to the group III-Nitride barrier layer. A drain electrically coupled to the group III-Nitride barrier layer; and a gate on the group III-Nitride barrier layer. Additionally, at least one of the drain and the source are arranged on the low resistance contact layer.

### FIELD OF THE DISCLOSURE

The disclosure relates to gallium nitride high-electron mobility transistors configured with a low resistance contact layer for source and/or drain contacts. The disclosure further relates to a process for implementing gallium nitride high-electron mobility transistors with a low resistance contact layer for source and/or drain contacts.

### BACKGROUND OF THE DISCLOSURE

Group III-Nitride based high-electron mobility transistors (HEMTs) are very promising candidates for high power radiofrequency (RF) applications, and also for low frequency high power switching applications since the material properties of Group III-nitrides, such as gallium nitride (GaN) and its alloys, enable achievement of high voltage and high current, along with high RF gain and linearity for RF applications. A typical Group III-nitride HEMT relies on the formation of a two-dimensional electron gas (2DEG) formed at the interface between a higher band-gap Group-III nitride (e.g., AlGaN) barrier layer and a lower band-gap Group-III nitride material (e.g., GaN) channel layer, where the smaller bandgap material has a higher electron affinity. The 2DEG is an accumulation layer in the smaller bandgap material and can contain a high electron concentration and high electron mobility.

Additionally, Group III-nitride HEMTs benefit from implementation of low resistance ohmic contacts. In this regard, existing structures and processes for low resistance ohmic contacts include: implantation and high temperature activation of n-type dopants in contact regions; Metal-Organic Chemical Vapour Deposition (MOCVD)-grown n-GaN epitaxial portions in contact regions; and/or Molecular-Beam Epitaxy (MBE)-grown n-GaN epitaxial portions on contact regions. In each of these cases, there is significant Capital Expenditures (CapEx) and maintenance cost with implementation. Additionally, these processes can be time-consuming. Furthermore, achieving low resistance contacts with high temperature activation anneal and/or high temperature epitaxial growth significantly degrades channel properties of Group III-nitride HEMT. For example, higher sheet resistance (Rsheet), lower mobility, and/or the like.

Accordingly, there is a need for structures and processes for low resistance ohmic contacts in Group-III nitride HEMTs.

### SUMMARY OF THE DISCLOSURE

In one aspect, a transistor includes a group III-Nitride channel layer. The transistor also includes a group III-Nitride barrier layer on the group III-Nitride channel layer, the group III-Nitride barrier layer having a higher bandgap than a bandgap of the group III-Nitride channel layer. The transistor furthermore includes a low resistance contact layer on the group III-Nitride barrier layer and/or on the group III-Nitride channel layer. The transistor in addition includes a source electrically coupled to the group III-Nitride barrier layer. The transistor moreover includes a drain electrically coupled to the group III-Nitride barrier layer. The transistor also includes a gate on the group III-Nitride barrier layer. The transistor furthermore includes where at least one of the drain and the source are arranged on the low resistance contact layer.

In one aspect, a process includes providing a group III-Nitride channel layer. The process also includes providing a group III-Nitride barrier layer on the group III-Nitride channel layer, the group III-Nitride barrier layer having a higher bandgap than a bandgap of the group III-Nitride channel layer. The process furthermore includes providing a low resistance contact layer on the group III-Nitride barrier layer and/or on the group III-Nitride channel layer. The process in addition includes providing and electrically coupling a source to the group III-Nitride barrier layer. The process moreover includes providing and electrically coupling a drain to the group III-Nitride barrier layer. The process also includes providing a gate on the group III-Nitride barrier layer. The process furthermore includes where at least one of the drain and the source are arranged on the low resistance contact layer.

In one aspect, a transistor includes active semiconductor layers structured and arranged by a first deposition technique. The transistor also includes a low resistance contact layer structured and arranged by a second deposition technique on at least one of the active semiconductor layers. The transistor furthermore includes a source electrically coupled to at least one of the active semiconductor layers. The transistor in addition includes a drain electrically coupled to at least one of the active semiconductor layers. The transistor moreover includes a gate on at least one of the active semiconductor layers. The transistor also includes where at least one of the drain and the source are arranged on the low resistance contact layer. The transistor furthermore includes where the first deposition technique is different from the second deposition technique.

In one aspect, a process includes providing active semiconductor layers structured and arranged by a first deposition technique. The process also includes providing a low resistance contact layer structured and arranged by a second deposition technique on at least one of the active semiconductor layers. The process furthermore includes providing a source electrically coupled to at least one of the active semiconductor layers. The process in addition includes providing a drain electrically coupled to at least one of the active semiconductor layers. The process moreover includes providing a gate on at least one of the active semiconductor layers. The process also includes where at least one of the drain and the source are arranged on the low resistance contact layer. The process furthermore includes where the first deposition technique is different from the second deposition technique.

Additional features, advantages, and aspects of the disclosure may be set forth or apparent from consideration of the following detailed description, drawings, and claims. Moreover, it is to be understood that both the foregoing summary of the disclosure and the following detailed description are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 shows a cross-sectional view of an aspect of a transistor according to the disclosure.

FIG. 2 shows a detailed partial cross-sectional view of the transistor of FIG. 1.

FIG. 3 shows a detailed partial cross-sectional view of another aspect of the transistor of FIG. 1.

FIG. 4 shows a cross-sectional view of another aspect of a transistor according to FIG. 1 and FIG. 2.

FIG. 5 shows a cross-sectional view of another aspect of a transistor according to FIG. 1 and FIG. 2.

FIG. 6 shows a cross-sectional view of another aspect of a transistor according to FIG. 1 and FIG. 2.

FIG. 7 shows a cross-sectional view of another aspect of a transistor according to FIG. 1 and FIG. 2.

FIG. 8 shows a cross-sectional view of another aspect of a transistor according to FIG. 1 and FIG. 2.

FIG. 9 shows a process of implementing a transistor according to the disclosure.

### DETAILED DESCRIPTION OF THE DISCLOSURE

The aspects of the disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects, as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings and in the different aspects disclosed.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The disclosure includes both extrinsic and intrinsic semiconductors. Intrinsic semiconductors are undoped (pure). Extrinsic semiconductors are doped, meaning an agent has been introduced to change the electron and hole carrier concentration of the semiconductor at thermal equilibrium. Both p-type and n-type semiconductors are disclosed, with p-types having a larger hole concentration than electron concentration, and n-types having a larger electron concentration than hole concentration.

Silicon carbide (SiC) has excellent physical and electronic properties, which should theoretically allow production of electronic devices that can operate at higher temperatures, higher power, and higher frequency than devices produced from silicon (Si) or gallium arsenide (GaAs) substrates. The high electric breakdown field of about 4×E6 V/cm, high saturated electron drift velocity of about 2.0×E7 cm/sec and high thermal conductivity of about 4.9 W/cm-° K. indicate that SiC would be suitable for high frequency and high power applications. In some aspects, the transistor of the present disclosure comprises Si, GaAs or other suitable substrates.

The disclosure is directed to a structure and a process for achieving very low contact resistance in GaN HEMT devices via the incorporation of sputtered n-GaN epitaxial portions. The disclosed structure and process is capable of delivering the low resistance required for high frequency operation (lower on resistance (Ron)) without employing high temperatures or high cost processes, such as for example MBE, MOCVD, implant, and/or the like. The disclosed structure and process can simultaneously improve the performance, manufacturability, processing time, and cost of the end product.

The disclosed structure and process may utilize a physical vapor deposition process that can leverage the lower temperature, high deposition rate inherent in the method. Furthermore, the doping ranges expected from this method are expected to be wider than those achievable with MOCVD, which has thermodynamically limited dopant incorporation rates. The higher dopant levels can drive down contact resistance beyond what is achievable via MOCVD regrown III-N epi.

The disclosed structure and process may include n-type sputtered GaN, deposited in the contact region of a GaN HEMT, to achieve low contact resistance critical for high frequency performance. Inclusion of a doped GaN film in this region lowers an electrostatic barrier for electron injection into the channel while being a low resistance film itself. Constructing ohmic contacts in this way can enable robust, high performance in RF devices. Typical effective doping range will be >1E19 cm-3.

The disclosed structure and process may be implemented on any and/or every RF technology. The disclosed structure and process may further be used in conjunction with existing implant and activation process to achieve the lowest possible contact resistance (Rc), in cases where that can sustain channel degradation associated with activation anneal. The disclosed structure and process may further be used to control doping in AlN or Al-rich AlGaN, which is otherwise incredibly challenging using processes that rely on thermodynamic equilibrium, for example MOCVD processes. The disclosed structure and process may further be used to selectively add low-doped Group III-N materials in regions of the channel to control capacitances and charge density, for example in drain access region.

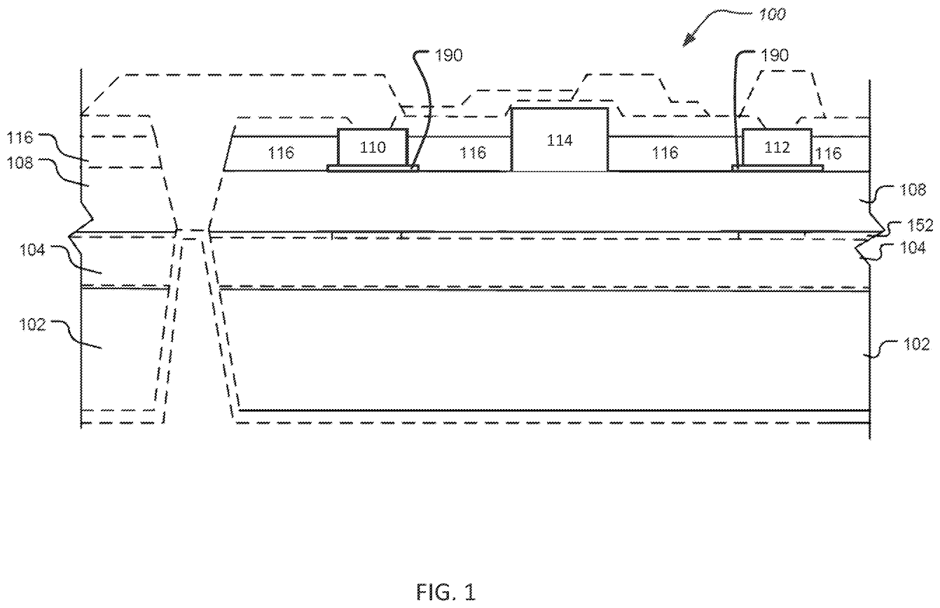

FIG. 1 shows a cross-sectional view of an aspect of a transistor according to the disclosure.

In particular, FIG. 1 shows a cross-sectional view of a transistor 100. The aspects of the transistor 100 illustrated in FIG. 1 and described in conjunction therewith may optionally be implemented in any other aspects the transistor 100 described herein. Moreover, other aspects the transistor 100 described herein may optionally be implemented in the transistor 100 of FIG. 1.

The transistor 100 may include a low resistance contact layer 190, a substrate layer 102, a channel layer 104, a barrier layer 108, a source 110, a drain 112, a spacer layer 116, and a gate 114. Each of these structures of the transistor 100 are described in greater detail below. In one aspect, a bandgap of the channel layer 104 may be less than a bandgap of the barrier layer 108 to form a two-dimensional electron gas (2DEG) at a heterointerface 152 between the channel layer 104 and barrier layer 108 when biased at an appropriate level. In one aspect, the heterointerface 152 may form and/or define a two-dimensional electron gas (2DEG) region. Additionally, the transistor 100 of FIG. 1 may further include any one or more other aspects as described herein.

In one or more aspects, the low resistance contact layer 190 may be formed, configured, structured, and/or arranged as described herein as a structure configured to achieve very low contact resistance in the transistor 100. In one or more aspects, the low resistance contact layer 190 may be formed, configured, structured, and/or arranged as described herein as a structure configured to achieve very low contact resistance in the transistor 100 for connection with the source 110 and/or the drain 112.

In one or more aspects, the low resistance contact layer 190 may be formed, configured, structured, and/or arranged as described herein as a sputtered structure, a structure formed by sputtering, a physical vapor deposited structure, a structure formed by physical vapor deposition, a film structure, and/or the like.

In one or more aspects, the low resistance contact layer 190 may include a Group III-nitride material such as AlₓIn_{y}Ga_{z}N where 0≤x≤1, 0≤y≤1, 0≤z≤1, and x+y+z=1. In one or more aspects, the low resistance contact layer 190 may include an n-type Group III-nitride material such as noted above.

In aspects, the low resistance contact layer 190 may include GaN, AlGaN, AlN, InAlGaN, and/or another suitable material. In aspects, the low resistance contact layer 190 may include an n-type GaN, AlGaN, AlN, InAlGaN, and/or another suitable material.

In one or more aspects, the low resistance contact layer 190 may include a doped material. In aspects, the low resistance contact layer 190 may be formed, configured, structured, and/or arranged as described herein to allow for doping ranges to be wider than those achievable with other processes, such as MOCVD processes and/or the like processes. In this regard, MOCVD processes have thermodynamically limited dopant incorporation rates. The higher dopant levels implemented by the low resistance contact layer 190 formed, configured, structured, and/or arranged as described herein can drive down contact resistance beyond what is achievable via MOCVD processes and/or the like processes such as for example MOCVD regrown III-N epi.

In one or more aspects, the low resistance contact layer 190 may be a doped material that is doped with Si, germanium, and/or other elements. In aspects, the low resistance contact layer 190 may be formed, configured, structured, and/or arranged as described herein with an effective doping range greater than 1E19 cm-3 In aspects, the low resistance contact layer 190 formed, configured, structured, and/or arranged as described herein may have a resistance lower than contacts formed via MOCVD processes and/or the like processes such as for example MOCVD regrown III-N epi.

In particular aspects, the low resistance contact layer 190 may be formed, configured, structured, and/or arranged as a GaN film structure, a n-type sputtered GaN structure, a structure formed by sputtering n-type GaN, a sputtered n-GaN epitaxial structure and/or the like.

In particular aspects, the low resistance contact layer 190 may be formed, configured, structured, and/or arranged as described herein without employing high temperatures processes such as for example MBE processes, MOCVD processes, implant processes, and/or the like processes. More specifically, the low resistance contact layer 190 may be formed, configured, structured, and/or arranged as described herein to deliver the low resistance required for high frequency operation, such as a lower on resistance (Ron), without employing high temperatures processes such as for example MBE processes, MOCVD processes, implant processes, and/or the like processes.

In particular aspects, the low resistance contact layer 190 may be formed, configured, structured, and/or arranged as described herein such that the low resistance contact layer 190 is configured to achieve a contact resistance of <0.1 ohm-mm, thereby achieving a lower Ron.

Accordingly, the low resistance contact layer 190 formed, configured, structured, and/or arranged as described herein may improve the performance, manufacturability, cost, processing time, and/or the like of the transistor 100.

In one or more aspects, the low resistance contact layer 190 may be arranged between the source 110 and the barrier layer 108 with intervening layers therebetween (not shown); and/or the low resistance contact layer 190 may be arranged between the drain 112 and the barrier layer 108 with intervening layers therebetween (not shown).

In one or more aspects, the low resistance contact layer 190 may be arranged between the source 110 and the barrier layer 108; and/or the low resistance contact layer 190 may be arranged between the drain 112 and the barrier layer 108.

In one or more aspects, the low resistance contact layer 190 may be arranged on the barrier layer 108 with intervening layers therebetween (not shown), the low resistance contact layer 190 may be arranged on the barrier layer 108, and/or the low resistance contact layer 190 may be arranged directly on the barrier layer 108.

In one or more aspects, the low resistance contact layer 190 may be arranged between the source 110 and the channel layer 104 with intervening layers therebetween (not shown); and/or the low resistance contact layer 190 may be arranged between the drain 112 and the channel layer 104 with intervening layers therebetween (not shown).

In one or more aspects, the low resistance contact layer 190 may be arranged between the source 110 and the channel layer 104; and/or the low resistance contact layer 190 may be arranged between the drain 112 and the channel layer 104.

In one or more aspects, the low resistance contact layer 190 may be arranged on the channel layer 104 with intervening layers therebetween (not shown), the low resistance contact layer 190 may be arranged on the channel layer 104, and/or the low resistance contact layer 190 may be arranged directly on the channel layer 104.

The substrate layer 102 may be made of Silicon Carbide (SiC). In some aspects, the substrate layer 102 may be a semi-insulating SiC substrate, a p-type substrate, an n-type substrate, and/or the like. In some aspects, the substrate layer 102 may be very lightly doped. In one aspect, the background impurity levels may be low. In one aspect, the background impurity levels may be 1E15/cm³ or less. In one aspect, the substrate layer 102 may be formed of SiC selected from the group of 6H, 4H, 15R, 3C SiC, or the like, and the SiC may be semi-insulating and doped with vanadium or any other suitable dopant or undoped of high purity with defects providing the semi-insulating properties.

In another aspect, the substrate layer 102 may be GaAs, GaN, or other material suitable for the applications described herein. In another aspect, the substrate layer 102 may include sapphire, spinel, ZnO, silicon, or any other material capable of supporting growth of Group III-nitride materials.

In one aspect, the channel layer 104 may be high purity GaN. In one aspect, the channel layer 104 may be high purity GaN that may be a low-doped n-type. In one aspect, the channel layer 104 may also use a higher band gap Group III-nitride layer as a back barrier, such as an AlGaN back barrier, on the other side of the channel layer 104 from the barrier layer 108 to achieve better electron confinement. In one aspect, the channel layer 104 may be a group III-Nitride channel layer.

In one aspect, the channel layer 104 may have a channel layer thickness defined as a distance between an upper surface of the substrate layer 102 and a lower surface of the barrier layer 108. In one aspect, the channel layer thickness may be less than 0.8 microns, less than 0.7 microns, less than 0.6 microns, less than 0.5 microns, or less than 0.4 microns. In one aspect, the channel layer thickness may have a range of 0.8 microns to 0.6 microns, 0.7 microns to 0.5 microns, 0.6 microns to 0.4 microns, 0.5 microns to 0.3 microns, 0.4 microns to 0.2 microns, or 0.7 microns to 0.3 microns.

In one aspect, the channel layer 104 includes a Group III-nitride, and, in particular includes GaN. The channel layer 104 may include a first channel sublayer and a second channel sublayer formed on the first channel sublayer. The first channel sublayer may be doped with Fe, Mg, Si, C, and/or the like. In one aspect, the transistor 100 may have an intervening layer(s) thickness defined as a length between an upper surface of the substrate layer 102 and a lower surface of the barrier layer 108. In one aspect, the intervening layer(s) thickness may be less than 0.8 microns, less than 0.7 microns, less than 0.6 microns, less than 0.5 microns, or less than 0.4 microns. In one aspect, the intervening layer(s) thickness may have a range of 0.8 microns to 0.6 microns, 0.7 microns to 0.5 microns, 0.6 microns to 0.4 microns, 0.5 microns to 0.3 microns, or 0.4 microns to 0.2 microns.

The barrier layer 108 may be formed on the channel layer 104. In one aspect, the barrier layer 108 may be formed directly on the channel layer 104, and in other aspects, the barrier layer 108 is formed on the channel layer 104 with intervening layer(s). Depending on the embodiment, the barrier layer 108 can include additional layers on the channel layer 104. For example an AlN layer or an AlGaN layer can be positioned on the channel layer 104 and an AlGaN layer with a lower percentage Al concentration can be positioned above the AlN layer or a higher Al percentage layer as described in U.S. Pat. No. 6,885,076 (Semiconductor laser device-filed Jun. 21, 2000) hereby incorporated by reference in its entirety. Furthermore, additional layers may be positioned above or in the barrier layer 108, such as spacer layers and/or other layers. Depending on the aspect, the channel layer 104 may be formed of different suitable materials such as a Group III-nitride such as AlₓIn_{y}Ga_{z}N where 0≤x≤1, 0≤y≤1, 0≤z≤1, and x+y+z=1, e.g., AlGaN, AlN, or InAlGaN, or another suitable material. In one aspect, the barrier layer 108 may be a group III-Nitride barrier layer. In one aspect, the barrier layer 108 may be AlGaN, and in another aspect the barrier layer 108 is AlN. In one aspect, the barrier layer 108 may be undoped. In one aspect, the barrier layer 108 may be doped. In one aspect, the barrier layer 108 may be an n-type material. In some aspects, the barrier layer 108 may have multiple layers of n-type material having different carrier concentrations. In one aspect, the barrier layer 108 may be a Group III-nitride or a combination thereof. In one aspect, the barrier layer 108 may include a first barrier sublayer on the channel layer 104 and a second barrier sublayer on the first barrier sublayer. The first barrier sublayer may include AlN. The second barrier sublayer may include AlₓGa₁₋ₓN. In one aspect, a bandgap of the channel layer 104 may be less than a bandgap of the barrier layer 108 to form a two-dimensional electron gas (2DEG) at a heterointerface 152 between the channel layer 104 and barrier layer 108 when biased at an appropriate level. In one aspect, a bandgap of the channel layer 104 that may be GaN may be less than a bandgap of the barrier layer 108 that may be AlGaN to form the two-dimensional electron gas (2DEG) at a heterointerface 152 between the channel layer 104 and barrier layer 108 when biased at an appropriate level.

In one or more aspects, the source 110 may be formed and/or defined by an open area for placement of the source 110 on the low resistance contact layer 190. The open area may be part of an ohmic window etch process. Additionally, the source 110 may be placed utilizing a self-aligned ohmic evaporation process. In this regard, the process may include etching through one or more of the spacer layer 116, the barrier layer 108, and/or the like to expose a surface of the low resistance contact layer 190, evaporation of the ohmic metal contacts, and a solvent-based liftoff.

In one or more aspects, the drain 112 may be formed and/or defined by an open area for placement of the drain 112 on the low resistance contact layer 190. The open area may be part of an ohmic window etch process. Additionally, the drain 112 may be placed utilizing a self-aligned ohmic evaporation process. In this regard, the process may include etching through one or more of the spacer layer 116, the barrier layer 108, and/or like to expose a surface of the low resistance contact layer 190, evaporation of the ohmic metal contacts, and a solvent-based liftoff.

In one aspect, the gate 114 may be formed on the barrier layer 108. The gate 114 may be arranged directly on the barrier layer 108 or the gate 114 may be arranged on intervening layer(s) on the barrier layer 108, such as an AlGaN layer on an AlN barrier layer. Other or additional intervening layers are possible. In this regard, the gate 114 may also include an implementation of the low resistance contact layer 190. In some aspects, the gate 114 may be deposited in a channel formed in the spacer layer 116, for example, a channel formed by etching or the like using semiconductor processing techniques understood by those of ordinary skill in the art. The gate 114 may have a T-shaped cross-section. Other gate configurations, gate shapes, and/or the like are contemplated by this disclosure for implementation as the gate 114.

The transistor 100 may include a spacer layer 116. The spacer layer 116 may be formed of SiN, AlO, SiO, SiO₂, AlN, or the like or combinations thereof. The spacer layer 116 may be provided on the barrier layer 108 or other intervening layers. To protect and separate the gate 114, the source 110, and/or the drain 112, the spacer layer 116 may be arranged on the barrier layer 108, on a side opposite the channel layer 104, adjacent the gate 114, the drain 112, and/or the source 110. The spacer layer 116 may be a passivation layer made of SIN, AlO, SiO, SiO₂, AlN, or the like, or a combination incorporating multiple layers thereof. In one aspect, the spacer layer 116 is a passivation layer made of SiN. In one aspect, the spacer layer 116 can be deposited using MOCVD, plasma chemical vapor deposition (CVD), hot-filament CVD, or sputtering. In one aspect, the spacer layer 116 may include deposition of Si₃N₄. In one aspect, the spacer layer 116 forms an insulating layer. In one aspect, the spacer layer 116 forms an insulator. In one aspect, the spacer layer 116 may be a dielectric. In one aspect, the spacer layer 116 may include a number of different layers of dielectrics or a combination of dielectric layers. In one aspect, the spacer layer 116 may be many different thicknesses, with a suitable range of thicknesses being approximately 0.05 to 2 microns. In one aspect, the spacer layer 116 may include a material such as a Group III nitride material having different Group III elements such as alloys of Al, Ga, or In, with a suitable spacer layer material being AlₓIn_{y}Ga_{z}N where 0≤x≤1, 0≤y≤1, 0≤z≤1, and x+y+z=1.

In aspects, the barrier layer 108 may be a group III-Nitride barrier layer. In aspects, the channel layer 104 may be a group III-Nitride channel layer. In aspects, at least the barrier layer 108 and the channel layer 104 may be configured as active semiconductor layers of the transistor 100. The transistor 100 may include other types of active semiconductor layers as well.

In aspects, the barrier layer 108 and the channel layer 104 may be structured and arranged by a first deposition technique, such as chemical vapor deposition, Lateral Epitaxial Overgrowth (LEO), and/or the like. In aspects, the low resistance contact layer 190 may be formed with a second deposition technique. In aspects, the second deposition technique may include forming the low resistance contact layer 190 as a sputtered structure, a structure formed by sputtering, a physical vapor deposited structure, a structure formed by physical vapor deposition, a film structure, and/or the like.

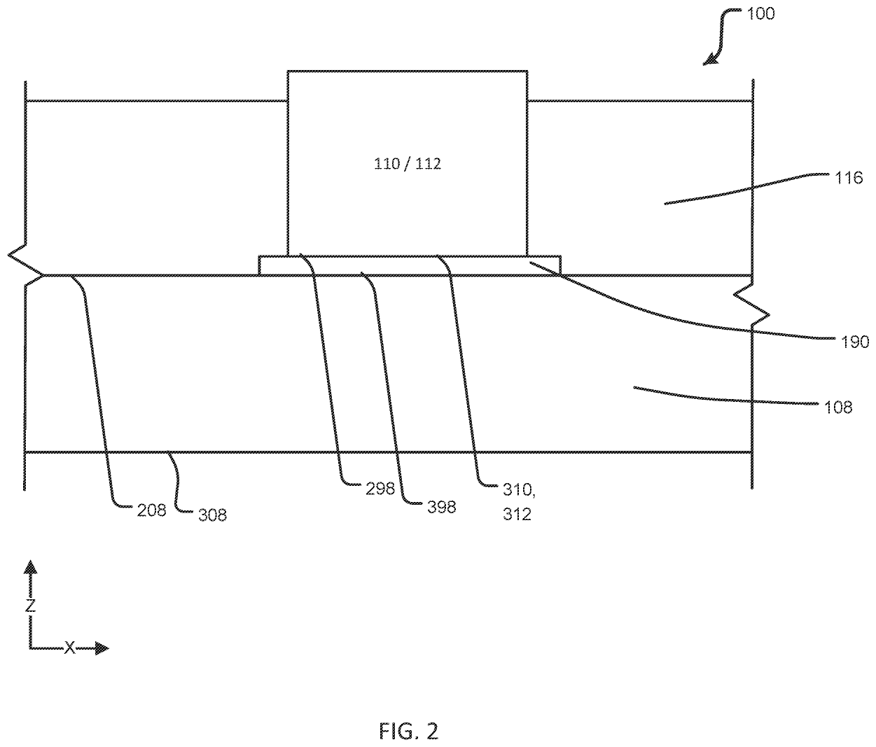

FIG. 2 shows a detailed partial cross-sectional view of the transistor of FIG. 1.

In particular, FIG. 2 illustrates further details of the structural configuration and arrangement of the source 110 and the drain 112 in a single illustration for ease of understanding. The aspects of the transistor 100 illustrated in FIG. 2 and described in conjunction therewith may optionally be implemented in any other aspects the transistor 100 described herein. Moreover, other aspects the transistor 100 described herein may optionally be implemented in the transistor 100 of FIG. 2.

However, the source 110 may have a structural configuration and/or arrangement consistent with FIG. 2 as described herein, which may be different from the drain 112 that has a structural configuration and/or arrangement consistent with FIG. 2 as described herein. Alternatively, the source 110 may have a structural configuration and/or arrangement consistent in regards to at least one aspect with the drain 112.

With reference to FIG. 2, the barrier layer 108 may include an upper barrier layer surface 208 and a lower barrier layer surface 308. The upper barrier layer surface 208 of the barrier layer 108 may extend generally along the x-axis or horizontal axis. The lower barrier layer surface 308 of the barrier layer 108 may extend generally along the x-axis or horizontal axis. The upper barrier layer surface 208 of the barrier layer 108 may extend generally parallel to the lower barrier layer surface 308 of the barrier layer 108. In this regard, generally is defined as being within 1°-20°. The upper barrier layer surface 208 of the barrier layer 108 may be defined as being vertically above the lower barrier layer surface 308 of the barrier layer 108 along the y-axis or vertical axis.

With further reference to FIG. 2, the low resistance contact layer 190 may include an upper contact layer surface 298 and a lower contact layer surface 398. The upper contact layer surface 298 of the low resistance contact layer 190 may extend generally along the x-axis or horizontal axis. The lower contact layer surface 398 of the low resistance contact layer 190 may extend generally along the x-axis or horizontal axis. The upper contact layer surface 298 of the low resistance contact layer 190 may extend generally parallel to the lower contact layer surface 398 of the low resistance contact layer 190. In this regard, generally is defined as being within 1°-20°. The upper contact layer surface 298 of the low resistance contact layer 190 may be defined as being vertically above the lower contact layer surface 398 of the low resistance contact layer 190 along the y-axis or vertical axis.

With further reference to FIG. 2, the source 110 may include an upper source surface and a lower source surface 310. The lower source surface 310 of the source 110 may extend generally along the x-axis or horizontal axis. Likewise, the drain 112 may include an upper drain surface and a lower drain surface 312. The lower drain surface 312 of the drain 112 may extend generally along the x-axis or horizontal axis.

Depending on the embodiment, the lower contact layer surface 398 of the low resistance contact layer 190 may be vertically on (along the y-axis) the upper barrier layer surface 208, may be vertically within (along the y-axis) the upper barrier layer surface 208, may be vertically below (along the y-axis) the upper barrier layer surface 208, may be within the barrier layer 108, and/or the like.

In one or more aspects, the lower contact layer surface 398 of the low resistance contact layer 190 may be arranged on the upper barrier layer surface 208 of the barrier layer 108 with intervening layers therebetween (not shown), the lower contact layer surface 398 of the low resistance contact layer 190 may be arranged on the upper barrier layer surface 208 of the barrier layer 108, and/or the lower contact layer surface 398 of the low resistance contact layer 190 may be arranged directly on the upper barrier layer surface 208 of the barrier layer 108.

In one or more aspects, the lower source surface 310 of the source 110 may be arranged on the upper contact layer surface 298 of the low resistance contact layer 190 with intervening layers therebetween (not shown), the lower source surface 310 of the source 110 may be arranged on the upper contact layer surface 298 of the low resistance contact layer 190, and/or the lower source surface 310 of the source 110 may be arranged directly on the upper contact layer surface 298 of the low resistance contact layer 190. In aspects, the upper contact layer surface 298 and/or the lower contact layer surface 398 may have dimensions slightly larger than the lower source surface 310. For example, the upper contact layer surface 298 and/or the lower contact layer surface 398 may have dimensions slightly larger than the lower source surface 310 along the X axis as illustrated in FIG. 2. In aspects, the low resistance contact layer 190, the upper contact layer surface 298 and/or the lower contact layer surface 398 may be symmetrical or may be asymmetrical. In aspects, the upper contact layer surface 298 and/or the lower contact layer surface 398 may have a similar but larger geometrical shape than the lower source surface 310. In aspects, the upper contact layer surface 298 and/or the lower contact layer surface 398 may have a same but larger geometrical shape (within manufacturing tolerances) as the lower source surface 310.

In one or more aspects, the lower drain surface 312 of the drain 112 may be arranged on the upper contact layer surface 298 of the low resistance contact layer 190 with intervening layers therebetween (not shown), the lower drain surface 312 of the drain 112 may be arranged on the upper contact layer surface 298 of the low resistance contact layer 190, and/or the lower drain surface 312 of the drain 112 may be arranged directly on the upper contact layer surface 298 of the low resistance contact layer 190. In aspects, the upper contact layer surface 298 and/or the lower contact layer surface 398 may have dimensions slightly larger than the lower drain surface 312. For example, the upper contact layer surface 298 and/or the lower contact layer surface 398 may have dimensions slightly larger than the lower drain surface 312 along the X axis as illustrated in FIG. 2. In aspects, the low resistance contact layer 190, the upper contact layer surface 298 and/or the lower contact layer surface 398 may be symmetrical or may be asymmetrical. In aspects, the upper contact layer surface 298 and/or the lower contact layer surface 398 may have a similar but larger geometrical shape than the lower drain surface 312. In aspects, the upper contact layer surface 298 and/or the lower contact layer surface 398 may have a same but larger geometrical shape (within manufacturing tolerances) as the lower drain surface 312.

In one or more aspects, the low resistance contact layer 190 may be a thick structure where a thickness may be defined by a distance between the upper contact layer surface 298 of the low resistance contact layer 190 and the lower contact layer surface 398 of the low resistance contact layer 190. In aspects, the thickness of the low resistance contact layer 190 may be 5 nm-500 nm, 5 nm-50 nm, 10 nm-50 nm, 50 nm-100 nm, 100 nm-150 nm, 150 nm-200 nm, 200 nm-250 nm, 250 nm-300 nm, 300 nm-350 nm, 350 nm-400 nm, 400 nm-450 nm, or 450 nm-500 nm.

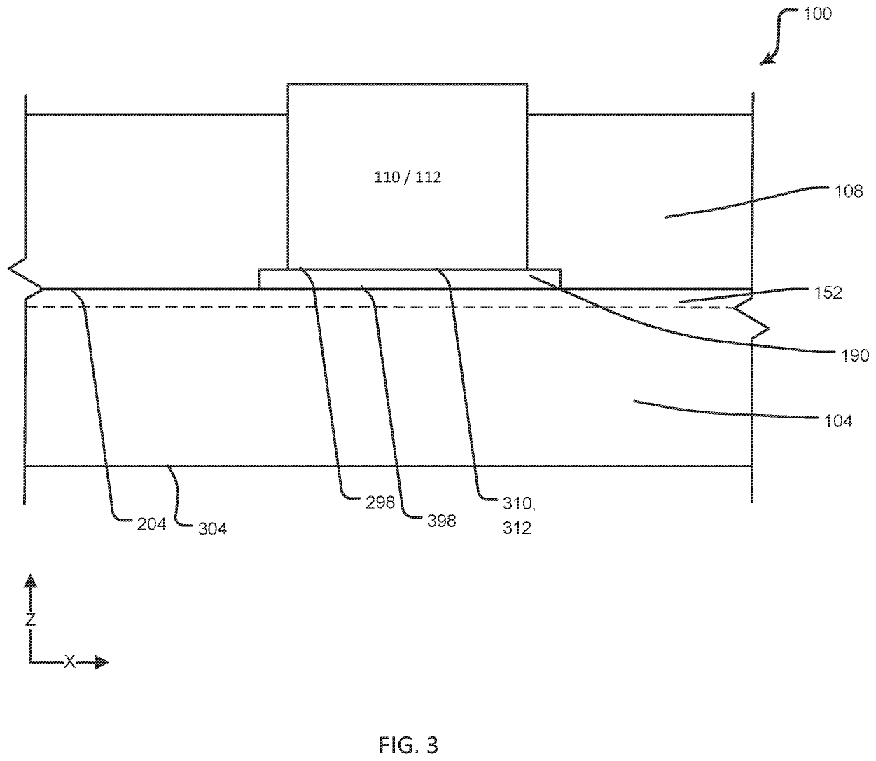

FIG. 3 shows a detailed partial cross-sectional view of another aspect of the transistor of FIG. 1.

In particular, FIG. 3 illustrates further details of the structural configuration and arrangement of the source 110 and the drain 112 in a single illustration for ease of understanding. The aspects of the transistor 100 illustrated in FIG. 3 and described in conjunction therewith may optionally be implemented in any other aspects the transistor 100 described herein. Moreover, other aspects the transistor 100 described herein may optionally be implemented in the transistor 100 of FIG. 3.

However, the source 110 may have a structural configuration and/or arrangement consistent with FIG. 3 as described herein, which may be different from the drain 112 that has a structural configuration and/or arrangement consistent with FIG. 3 as described herein. Alternatively, the source 110 may have a structural configuration and/or arrangement consistent in regards to at least one aspect with the drain 112.

With reference to FIG. 3, the channel layer 104 may include an upper channel layer surface 204 and a lower channel layer surface 304. The upper channel layer surface 204 of the channel layer 104 may extend generally along the x-axis or horizontal axis. The lower channel layer surface 304 of the channel layer 104 may extend generally along the x-axis or horizontal axis. The upper channel layer surface 204 of the channel layer 104 may extend generally parallel to the lower channel layer surface 304 of the channel layer 104. In this regard, generally is defined as being within 1°-20°. The upper channel layer surface 204 of the channel layer 104 may be defined as being vertically above the lower channel layer surface 304 of the channel layer 104 along the y-axis or vertical axis.

With further reference to FIG. 3, the low resistance contact layer 190 may include an upper contact layer surface 298 and a lower contact layer surface 398. The upper contact layer surface 298 of the low resistance contact layer 190 may extend generally along the x-axis or horizontal axis. The lower contact layer surface 398 of the low resistance contact layer 190 may extend generally along the x-axis or horizontal axis. The upper contact layer surface 298 of the low resistance contact layer 190 may extend generally parallel to the lower contact layer surface 398 of the low resistance contact layer 190. In this regard, generally is defined as being within 1°-20°. The upper contact layer surface 298 of the low resistance contact layer 190 may be defined as being vertically above the lower contact layer surface 398 of the low resistance contact layer 190 along the y-axis or vertical axis.

With further reference to FIG. 3, the source 110 may include an upper source surface and a lower source surface 310. The lower source surface 310 of the source 110 may extend generally along the x-axis or horizontal axis. Likewise, the drain 112 may include an upper drain surface and a lower drain surface 312. The lower drain surface 312 of the drain 112 may extend generally along the x-axis or horizontal axis.

Depending on the embodiment, the lower contact layer surface 398 of the low resistance contact layer 190 may be vertically on (along the y-axis) the upper channel layer surface 204, may be vertically within (along the y-axis) the upper channel layer surface 204, may be vertically below (along the y-axis) the upper channel layer surface 204, may be within the channel layer 104, and/or the like. In aspects, the low resistance contact layer 190 may be arranged in a recess in the barrier layer 108.

In one or more aspects, the lower contact layer surface 398 of the low resistance contact layer 190 may be arranged on the upper channel layer surface 204 of the channel layer 104 with intervening layers therebetween (not shown), the lower contact layer surface 398 of the low resistance contact layer 190 may be arranged on the upper channel layer surface 204 of the channel layer 104, and/or the lower contact layer surface 398 of the low resistance contact layer 190 may be arranged directly on the upper channel layer surface 204 of the channel layer 104.

In one or more aspects, the lower source surface 310 of the source 110 may be arranged on the upper contact layer surface 298 of the low resistance contact layer 190 with intervening layers therebetween (not shown), the lower source surface 310 of the source 110 may be arranged on the upper contact layer surface 298 of the low resistance contact layer 190, and/or the lower source surface 310 of the source 110 may be arranged directly on the upper contact layer surface 298 of the low resistance contact layer 190. In aspects, the low resistance contact layer 190 and/or the lower source surface 310 may be arranged in a recess in the barrier layer 108.

In one or more aspects, the lower drain surface 312 of the drain 112 may be arranged on the upper contact layer surface 298 of the low resistance contact layer 190 with intervening layers therebetween (not shown), the lower drain surface 312 of the drain 112 may be arranged on the upper contact layer surface 298 of the low resistance contact layer 190, and/or the lower drain surface 312 of the drain 112 may be arranged directly on the upper contact layer surface 298 of the low resistance contact layer 190. In aspects, the low resistance contact layer 190 and/or the lower drain surface 312 may be arranged in a recess in the barrier layer 108.

In one or more aspects, the low resistance contact layer 190 may be a thick structure where a thickness may be defined by a distance between the upper contact layer surface 298 of the low resistance contact layer 190 and the lower contact layer surface 398 of the low resistance contact layer 190. In aspects, the thickness of the low resistance contact layer 190 may be 5 nm-500 nm, 5 nm-50 nm, 10 nm-50 nm, 50 nm-100 nm, 100 nm-150 nm, 150 nm-200 nm, 200 nm-250 nm, 250 nm-300 nm, 300 nm-350 nm, 350 nm-400 nm, 400 nm-450 nm, or 450 nm-500 nm.

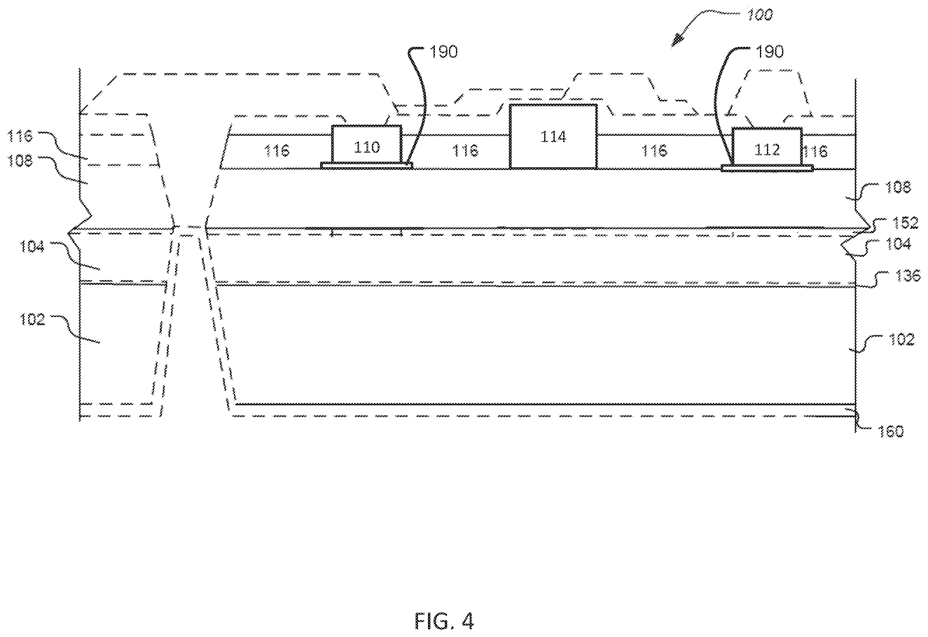

FIG. 4 shows a cross-sectional view of another aspect of a transistor according to FIG. 1 and FIG. 2.

FIG. 4 shows different aspects and/or features of the transistor 100 of the present disclosure with like reference numerals representing the same or analogous parts in the various aspects and figures of the disclosure. It should be understood that a feature described in one aspect of the disclosure or illustrated in a Figure can be optionally added to another aspect or replace a feature in another aspect. In this regard, the transistor 100 of FIG. 4 may further optionally include any one or more other aspects as described herein.

With reference to FIG. 4, the transistor 100 may include a nucleation layer 136. In this regard, depending on the material of the substrate layer 102, the nucleation layer 136 may be formed on the substrate layer 102 to reduce a lattice mismatch between the substrate layer 102 and a next layer in the transistor 100. In one aspect, the nucleation layer 136 may be formed directly on the substrate layer 102. In other aspects, the nucleation layer 136 may be formed on the substrate layer 102 with intervening layer(s), such as SiC epitaxial layer(s) formed on a SiC material implementation of the substrate layer 102. The nucleation layer 136 may include different suitable materials, such as a Group III-Nitride material, e.g., AlₓIn_{y}Ga_{z}N where 0≤x≤1, 0≤y≤1, 0≤z≤1, and x+y+z=1. The nucleation layer 136 may be formed on the substrate layer 102 using known semiconductor growth techniques such as Metal Oxide Chemical Vapor Deposition (MOCVD), Hydride Vapor Phase Epitaxy (HVPE), Molecular Beam Epitaxy (MBE), and/or the like. In some aspects, the nucleation layer 136 may be AlN or AlGaN, such as undoped AlN or AlGaN.

In some aspects, the channel layer 104 is formed directly on the nucleation layer 136 or on the nucleation layer 136 with intervening layer(s). In some aspects, the channel layer 104 is formed to include the nucleation layer 136. Also, additional layers can be included below or in the channel layer 104 such as a confinement layer, and/or other layers. Depending on the aspect, the channel layer 104 may be formed of different suitable materials such as a Group III-nitride such as AlₓIn_{y}Ga_{z}N where 0≤x≤1, 0≤y≤1, 0≤z≤1, and x+y+z=1, e.g., GAN, Aluminum Gallium Nitride (AlGaN), Aluminum Nitride (AlN), and the like, or another suitable material. In one aspect, the channel layer 104 is formed of GaN. The channel layer 104 or portions thereof may be doped with dopants, such as, Fe and/or C or alternatively can be wholly or partly undoped. In one aspect, the channel layer 104 is directly on the substrate layer 102.

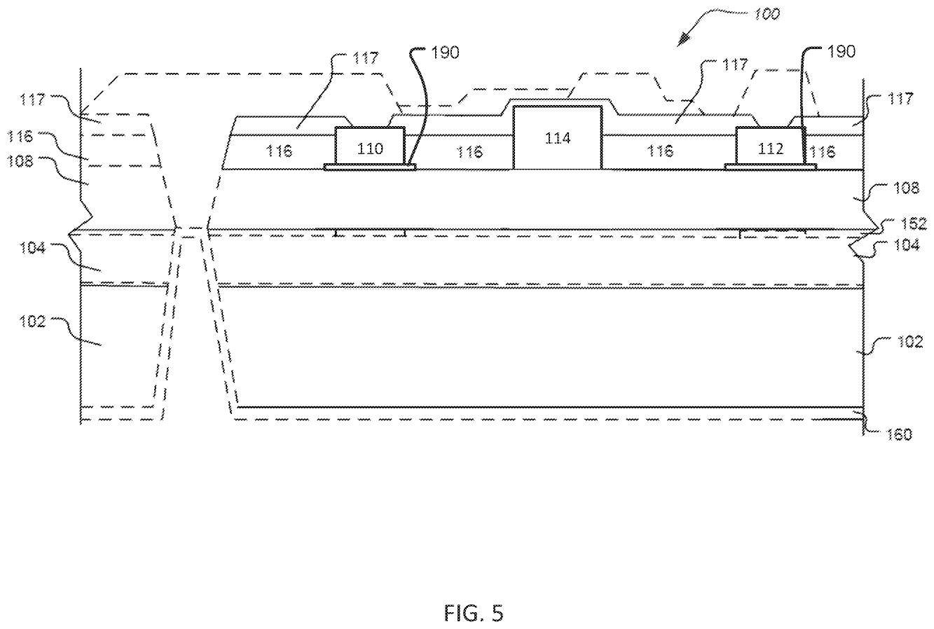

FIG. 5 shows a cross-sectional view of another aspect of a transistor according to FIG. 1 and FIG. 2.

FIG. 5 shows different aspects and/or features of the transistor 100 of the present disclosure with like reference numerals representing the same or analogous parts in the various aspects and figures of the disclosure. It should be understood that a feature described in one aspect of the disclosure or illustrated in a Figure can optionally be added to another aspect or replace a feature in another aspect. In this regard, the transistor 100 of FIG. 5 may optionally further include any one or more other aspects as described herein.

With reference to FIG. 5, the transistor 100 may include a spacer layer 117. In some aspects, the spacer layer 117 may be formed on the spacer layer 116 and the gate 114. In one aspect, the spacer layer 116 may be provided on the barrier layer 108. In one aspect, the spacer layer 117 may be provided over the gate 114 and the spacer layer 116. In one aspect, the spacer layer 117 may include a non-conducting material such as a dielectric. In one aspect, the spacer layer 117 may include a number of different layers of dielectrics or a combination of dielectric layers. In one aspect, the spacer layer 117 may be many different thicknesses, with a suitable range of thicknesses being approximately 0.05 to 2 microns. In one aspect, the spacer layer 117 may include a material such as a Group Ill nitride material having different Group III elements such as alloys of Al, Ga, or In, with a suitable spacer layer material being AlxInyGazN where 0≤x≤1, 0≤y≤1, 0≤z≤1, and x+y+z=1.

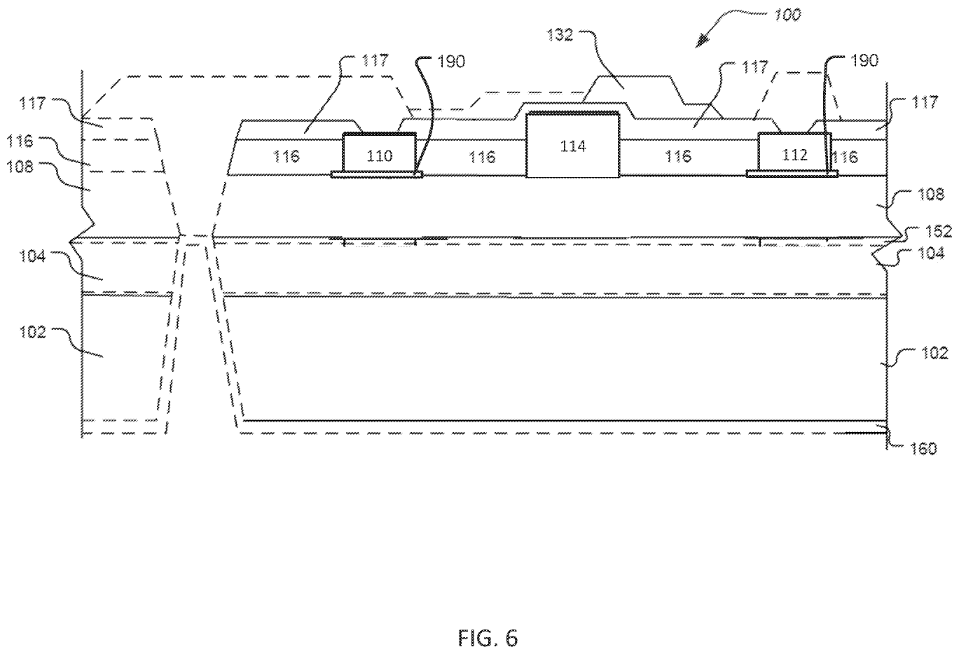

FIG. 6 shows a cross-sectional view of another aspect of a transistor according to FIG. 1 and FIG. 2.

FIG. 6 shows different aspects and/or features of the transistor 100 of the present disclosure with like reference numerals representing the same or analogous parts in the various aspects and figures of the disclosure. It should be understood that a feature described in one aspect of the disclosure or illustrated in a Figure can optionally be added to another aspect or replace a feature in another aspect. In this regard, the transistor 100 of FIG. 6 may optionally further include any one or more other aspects as described herein.

With reference to FIG. 6, the transistor 100 may include a field plate 132. In some aspects, the spacer layer 117 may be formed on the spacer layer 116 and the gate 114, and the field plate 132 may be provided on the spacer layer 117.

In other aspects, for example, the spacer layer 116 may be formed on the barrier layer 108 and on the gate 114. In such aspects, the field plate 132 can be formed directly on the spacer layer 116. Other multiple field plate configurations are possible with the field plate 132 overlapping or non-overlapping with the gate 114 and/or multiple field plates 132 being used.

In one aspect, the field plate 132 may be arranged on the spacer layer 117 between the gate 114 and the drain 112. In one aspect, the field plate 132 may be deposited on the spacer layer 117 between the gate 114 and the drain 112. In one aspect, the field plate 132 may be electrically connected to one or more other components in the transistor 100. In one aspect, the field plate 132 may not be electrically connected to any other components of the transistor 100. In some aspects, the field plate 132 may be adjacent the gate 114 and an additional implementation of the spacer layer 117 of dielectric material may be included at least partially over the gate 114 to isolate the gate 114 from the field plate 132. In some aspects, the field plate 132 may overlap the gate 114 and an additional configuration of the spacer layer 117 of dielectric material may be included at least partially over the gate 114 to isolate the gate 114 from the field plate 132.

The field plate 132 may extend different distances from the edge of the gate 114, with a suitable range of distances being approximately 0.1 to 2 microns. In some aspects, the field plate 132 may include many different conductive materials with a suitable material being a metal, or combinations of metals, deposited using standard metallization methods. In one aspect, the field plate 132 may include titanium, gold, nickel, titanium/gold, nickel/gold, or the like.

In one aspect, the field plate 132 may be formed on the spacer layer 117 between the gate 114 and the drain 112, with the field plate 132 being in proximity to the gate 114 but not overlapping the gate 114. In one aspect, a space between the gate 114 and field plate 132 may be wide enough to isolate the gate 114 from the field plate 132, while being small enough to maximize a field effect provided by the field plate 132.

In certain aspects, the field plate 132 may reduce a peak operating electric field in the transistor 100. In certain aspects, the field plate 132 may reduce the peak operating electric field in the transistor 100 and may increase the breakdown voltage of the transistor 100. In certain aspects, the field plate 132 may reduce the peak operating electric field in the transistor 100 and may reduce trapping in the transistor 100. In certain aspects, the field plate 132 may reduce the peak operating electric field in the transistor 100 and may reduce leakage currents in the transistor 100.

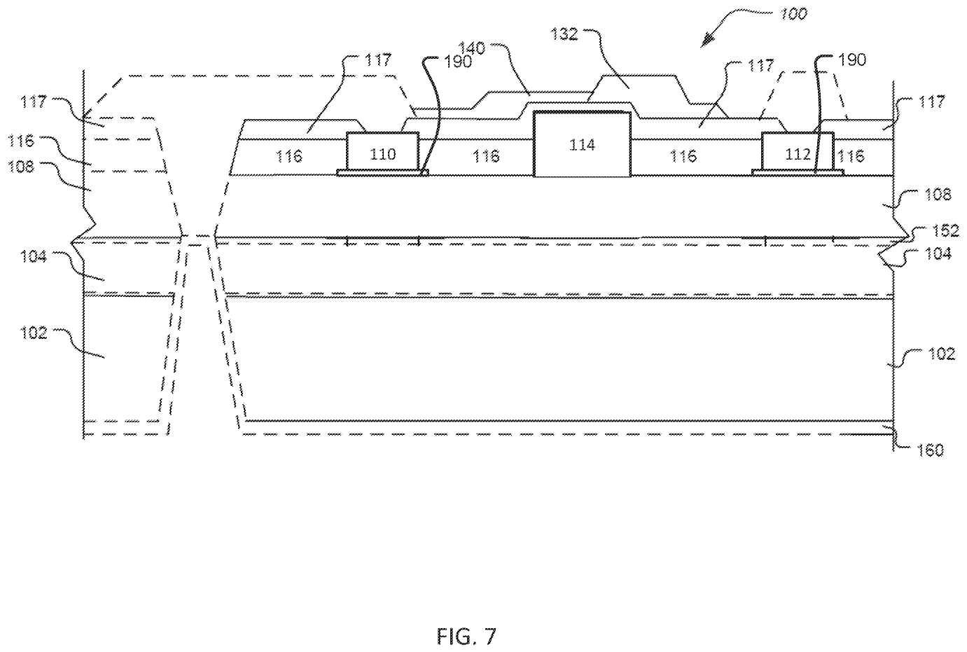

FIG. 7 shows a cross-sectional view of another aspect of a transistor according to FIG. 1 and FIG. 2.

FIG. 7 shows different aspects and/or features of the transistor 100 of the present disclosure with like reference numerals representing the same or analogous parts in the various aspects and figures of the disclosure. It should be understood that a feature described in one aspect of the disclosure or illustrated in a Figure can optionally be added to another aspect or replace a feature in another aspect. In this regard, the transistor 100 of FIG. 7 may optionally further include any one or more other aspects as described herein.

With reference to FIG. 7, the transistor 100 may include in certain aspects the field plate 132 as described herein and a connection 140. In this regard, the field plate 132 may be electrically connected to the source 110 through the connection 140. Alternatively, the field plate 132 may be electrically connected to the gate 114 through the connection 140. Alternatively, the field plate 132 may be electrically connected to other portions of the transistor 100 through the connection 140.

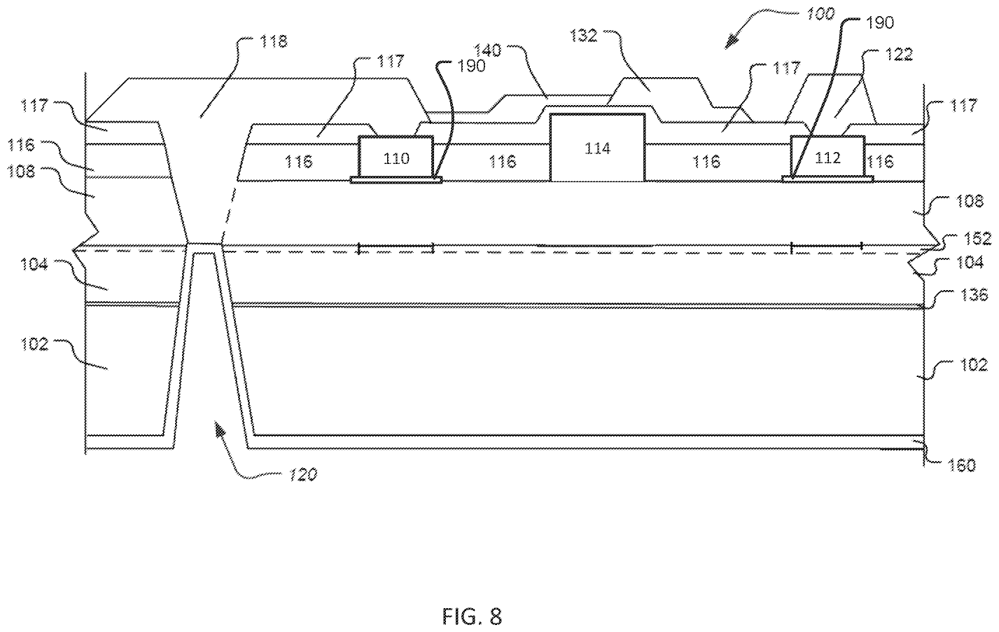

FIG. 8 shows a cross-sectional view of another aspect of a transistor according to FIG. 1 and FIG. 2.

FIG. 8 shows different aspects and/or features of the transistor 100 of the present disclosure with like reference numerals representing the same or analogous parts in the various aspects and figures of the disclosure. It should be understood that a feature described in one aspect of the disclosure or illustrated in a Figure can optionally be added to another aspect or replace a feature in another aspect. In this regard, the transistor 100 of FIG. 8 may optionally further include any one or more other aspects as described herein.

With reference to FIG. 8, the transistor 100 may include one or more of a source contact 118, a drain contact 122, a recess 120, and/or a back metal portion 160. In one aspect, the source 110 of the transistor 100 may have the source contact 118. The source contact 118 may be electrically connected to the source 110. The source contact 118 may be arranged at least partially on the spacer layer 117 and/or the spacer layer 116. The source contact 118 may be directly or indirectly connected to the source 110.

In one aspect, the source contact 118 may be formed at least in part in the recess 120. The recess 120 may be provided in the channel layer 104 and/or the barrier layer 108. The recess 120 may extend down to the channel layer 104 and/or the barrier layer 108 to allow for the source contact 118 to be created there. The recess 120 may be formed by etching, and may also use a material to define the recess 120. The material may be removed after the recess 120 has been created. In further aspects, the recess 120 may also include a corresponding recess extending through the substrate layer 102.

In one aspect, the drain 112 of the transistor 100 may have the drain contact 122. The drain contact 122 may be electrically connected to the drain 112. The drain contact 122 may be arranged at least partially on the spacer layer 117 and/or the spacer layer 116. The drain contact 122 may be directly or indirectly connected to the drain 112.

In one aspect, the substrate layer 102 of the transistor 100 may include the back metal portion 160. The back metal portion 160 may be Au, Ag, Al, Pt, Ti, Si, Ni, Al, and/or Copper (Cu). Other suitable highly conductive metals may also be used for the back metal portion 160. In one or more aspects, the back metal portion 160 may electrically couple to the source contact 118. In one or more aspects, the back metal portion 160 may extend into the recess 120 and electrically couple to the source contact 118.

In another aspect, one or more metal overlayers may be provided on one or more of the source 110, the source contact 118, the drain 112, the drain contact 122, and/or the gate 114. The overlayers may be Au, Ag, Al, Pt, Ti, Si, Ni, Al, and/or Copper (Cu). Other suitable highly conductive metals may also be used for the overlayers. In one or more aspects, the metal overlayer may electrically couple to the source contact 118 and/or the drain contact 122. In another aspect, the source 110, the source contact 118, the drain 112, the drain contact 122, and/or the gate 114 may include Au, Ag, Al, Pt, Ti, Si, Ni, Al, and/or Copper (Cu). Other suitable highly conductive metals may also be used.

In aspects of the transistor 100 of the disclosure, the channel layer 104 may include an upper portion of high purity GaN and the channel layer 104 may also include a lower portion that may form an AlGaN back barrier to achieve better electron confinement. In one aspect, the lower portion that forms the back barrier may be AlGaN of n type. The back barrier construction may be implemented in any of the aspects of the disclosure.

In aspects of the transistor 100 of the disclosure, the channel layer 104 may be designed to be of the high purity type where the Fermi level is in the upper half of the bandgap, which minimizes slow trapping effects normally observed in GaN HEMTs. In this regard, the traps under the Fermi level are filled always and thus slow transients may be prevented. In some aspects, the channel layer 104 may be as thin as possible consistent with achieving good crystalline quality. Applicants have already demonstrated 0.4 μm layers with good quality.

In aspects of the transistor 100 of the disclosure, a AlₓIn_{y}Ga_{z}N where 0≤x≤1, 0≤y≤1, 0≤z≤1, and x+y+z=1 nucleation layer 136 or channel layer 104 may be grown on the substrate layer 102 via an epitaxial crystal growth method, such as MOCVD (Metalorganic Chemical Vapor Deposition), HVPE (Hydride Vapor Phase Epitaxy) or MBE (Molecular Beam Epitaxy). The formation of the nucleation layer 136 may depend on the material of the substrate layer 102.

In aspects of the transistor 100 of the disclosure, the channel layer 104 may be formed with Lateral Epitaxial Overgrowth (LEO). LEO can, for example, improve the crystalline quality of GaN layers. When semiconductor layers of a HEMT are epitaxial, the layer upon which each epitaxial layer is grown may affect the characteristics of the device. For example, LEO may reduce dislocation density in epitaxial GaN layers.

In aspects of the transistor 100 of the disclosure, the substrate layer 102 may be silicon carbide and include a carbon face. In one aspect, the substrate layer 102 may be silicon carbide and include a carbon face arranged adjacent the channel layer 104. In one aspect, the substrate layer 102 may be silicon carbide and include a carbon face and the substrate layer 102 may be flipped so as to be arranged adjacent the channel layer 104. In this aspect, the channel layer 104 may be GaN having a nitrogen face adjacent the carbon face of the substrate layer 102. In one aspect, the channel layer 104 may be GaN having alternating GaN and N layers with a N layer and/or a nitrogen face adjacent the carbon face of the substrate layer 102.

In aspects of the transistor 100 of the disclosure, the channel layer 104 may include nonpolar GaN. In one aspect, the channel layer 104 may include semipolar GaN. In one aspect, the channel layer 104 may include hot wall epitaxy. In one aspect, the channel layer 104 may include hot wall epitaxy having a thickness in the range of. 15 microns to 0.25 microns, 0.2 microns to 0.3 microns, 0.25 microns to 0.35 microns, 0.3 microns to 0.35 microns, 0.35 microns to 0.4 microns, 0.4 microns to 0.45 microns, 0.45 microns to 0.5 microns, 0.5 microns to 0.55 microns, or 0.15 microns to 0.55 microns.

In aspects of the transistor 100 of the disclosure, a gate contact may be provided for the gate 114 in between the source 110 and the drain 112. Furthermore, in certain aspects of the disclosure, the gate contact may be disposed on the barrier layer 108. In one aspect, the gate contact may be disposed directly on the barrier layer 108.

In aspects of the transistor 100 of the disclosure, the gate 114 may be formed of platinum (Pt), nickel (Ni), and/or gold (Au), however, other metals known to one skilled in the art to achieve the Schottky effect, may be used. In one aspect, the gate 114 may include a Schottky gate contact that may have a three-layer structure. Such a structure may have advantages because of the high adhesion of some materials. In one aspect, the gate 114 may further include an overlayer of highly conductive metal. In one aspect, the gate 114 may be configured as a T-shaped gate.

In aspects of the transistor 100 of the disclosure, the contacts of the source 110, the gate 114, and/or the drain 112 may include Al, Ti, Si, Ni, and/or Pt. In some aspects, the source contact 118 may include Al, Ti, Si, Ni, and/or Pt. In particular aspects, the material of the contacts of the source 110, the gate 114, and/or the drain 112 may be the same material as the source contact 118. In this aspect, utilizing the same material may be beneficial in that manufacturing may be easier, simplified, and/or less costly. In other aspects, the material of the contacts of the source 110, the gate 114, the drain 112, and the source contact 118 may be different.

In the aspects of the disclosure, the heterointerface 152 may be between the barrier layer 108 and the channel layer 104. In one aspect, the source 110 and the drain 112 electrodes may be formed making ohmic contacts such that an electric current flows between the source 110 and the drain 112 electrodes via a two-dimensional electron gas (2DEG) induced at the heterointerface 152 between the channel layer 104 and the barrier layer 108 when a gate 114 electrode is biased at an appropriate level. In one aspect, the heterointerface 152 may be in the range of 0.005 μm to 0.007 μm, 0.007 μm to 0.009 μm, and 0.009 μm to 0.011 μm.

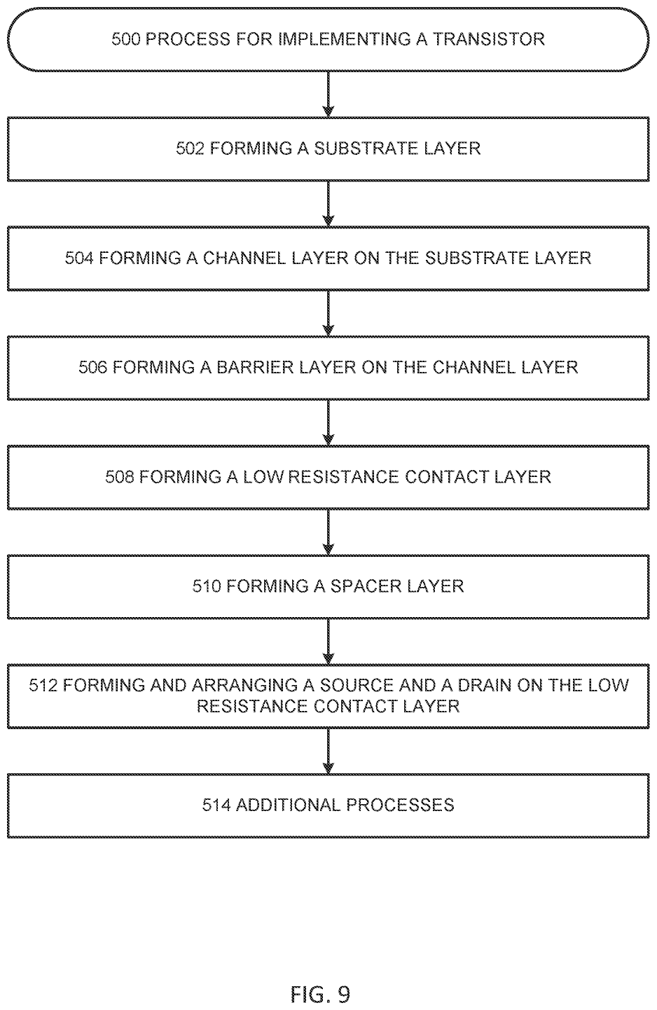

FIG. 9 shows a process of implementing a transistor according to the disclosure.

In particular, FIG. 9 shows an exemplary process for implementing a transistor 500 of the disclosure. In particular, it should be noted that the process for implementing a transistor 500 is merely exemplary and may be modified consistent with the various aspects disclosed herein. Moreover, the process for implementing a transistor 500 of the disclosure may include a process of manufacturing the transistor 100. It should be noted that the process for implementing a transistor 500 may be performed in a different order consistent with the aspects described above. Moreover, the process for implementing a transistor 500 may be modified to have more or fewer process steps consistent with the various aspects disclosed herein.

The process for implementing a transistor 500 of the disclosure may include forming a substrate layer 502. In this regard, the forming a substrate layer 502 may include any one or more materials, structures, arrangements, processes, and/or the like of the substrate layer 102 as described herein. Moreover, one or more proceeding or subsequent processes may also be implemented consistent with the disclosure.

The substrate layer 102 may be made of Silicon Carbide (SiC). In some aspects, the substrate layer 102 may be a semi-insulating SiC substrate, a p-type substrate, an n-type substrate, and/or the like. In some aspects, the substrate layer 102 may be very lightly doped. In one aspect, the background impurity levels may be low. In one aspect, the background impurity levels may be 1E15/cm³ or less. The substrate layer 102 may be formed of SiC selected from the group of 6H, 4H, 15R, 3C SiC, or the like. In another aspect, the substrate layer 102 may be GaAs, GaN, or other material suitable for the applications described herein. In another aspect, the substrate layer 102 may include sapphire, spinel, ZnO, silicon, or any other material capable of supporting growth of Group III-nitride materials.

The process for implementing a transistor 500 of the disclosure may include forming a channel layer on the substrate layer 504. In this regard, the forming a channel layer on the substrate layer 504 may include any one or more materials, structures, arrangements, processes, and/or the like of the channel layer 104 as described herein. Moreover, one or more proceeding or subsequent processes may also be implemented consistent with the disclosure.

In aspects, the forming a channel layer on the substrate layer 504 may include forming the channel layer 104 by a first deposition technique. For example, the first deposition technique may include chemical vapor deposition, Lateral Epitaxial Overgrowth (LEO), and/or the like. The channel layer 104 may be grown or deposited on the substrate layer 102. In one aspect, the channel layer 104 may be GaN. In another aspect, the channel layer 104 may be formed with LEO. In one aspect, a nucleation layer 136 may be formed on the substrate layer 102 and the channel layer 104 may be formed on the nucleation layer 136. The channel layer 104 may be grown or deposited on the nucleation layer 136. In one aspect, the channel layer 104 may be GaN. In another aspect, the channel layer 104 may be formed with LEO.

The process for implementing a transistor 500 of the disclosure may include forming a barrier layer on the channel layer 506. In this regard, the forming a barrier layer on the channel layer 506 may include any one or more materials, structures, arrangements, processes, and/or the like of the barrier layer 108 as described herein. Moreover, one or more proceeding or subsequent processes may also be implemented consistent with the disclosure.

In aspects, the forming a barrier layer on the channel layer 506 may include forming the barrier layer 108 by a first deposition technique. For example, the first deposition technique may include chemical vapor deposition, Lateral Epitaxial Overgrowth (LEO), and/or the like. The barrier layer 108 may be an n-type conductivity layer or may be undoped. In one aspect, the barrier layer 108 may be AlGaN. The barrier layer 108 may be formed on the channel layer 104. In one aspect, the barrier layer 108 may be formed directly on the channel layer 104, and in other aspects, the barrier layer 108 is formed on the channel layer 104 with intervening layer(s). Depending on the aspect, the channel layer 104 may be formed of different suitable materials such as a Group III-nitride such as AlxInyGazN where 0≤x≤1, 0≤y≤1, 0≤z≤1, and x+y+z=1, e.g., AlGaN, AlN, or InAlGaN, or another suitable material. In one aspect, the barrier layer 108 may be AlGaN, and in another aspect the barrier layer 108 is AlN. In one aspect, the barrier layer 108 may be undoped. In one aspect, the barrier layer 108 may be doped. In one aspect, the barrier layer 108 may be an n-type material. In some aspects, the barrier layer 108 may have multiple layers of n-type material having different carrier concentrations. In one aspect, the barrier layer 108 may be a Group III-nitride or a combination thereof. In one aspect, a bandgap of the channel layer 104 may be less than a bandgap of the barrier layer 108 to form a two-dimensional electron gas (2DEG) at a heterointerface 152 between the channel layer 104 and barrier layer 108 when biased at an appropriate level. In one aspect, a bandgap of the channel layer 104 that may be GaN may be less than a bandgap of the barrier layer 108 that may be AlGaN to form the two-dimensional electron gas (2DEG) at a heterointerface 152 between the channel layer 104 and the barrier layer 108 when biased at an appropriate level.

The process for implementing a transistor 500 of the disclosure may include forming a low resistance contact layer 508. In this regard, the forming a low resistance contact layer 508 may include any one or more materials, structures, arrangements, processes, and/or the like of the low resistance contact layer 190 as described herein. Moreover, one or more proceeding or subsequent processes may also be implemented consistent with the disclosure.

In aspects, the forming a low resistance contact layer 508 may include forming the low resistance contact layer 190 by a second deposition technique as described herein. In aspects, the second deposition technique is different from the first deposition technique. For example, the forming a low resistance contact layer 508 may include forming the low resistance contact layer 190 as a sputtered structure, a structure formed by sputtering, a physical vapor deposited structure, a structure formed by physical vapor deposition, a film structure, and/or the like. In aspects, the low resistance contact layer 190 may be formed by sputter deposition on the upper barrier layer surface 208 of the barrier layer 108 and/or the upper channel layer surface 204 of the channel layer 104. In this regard, the forming a low resistance contact layer 508 may include depositing the low resistance contact layer 190 on the upper barrier layer surface 208 of the barrier layer 108 and/or the upper channel layer surface 204 of the channel layer 104 as a thin film by sputtering.

Further, the forming a low resistance contact layer 508 may include eroding a material from a target source and depositing the material as the low resistance contact layer 190 onto the upper barrier layer surface 208 of the barrier layer 108 and/or the upper channel layer surface 204 of the channel layer 104. The target source material may be gallium, indium, and/or another Group III-nitride material. Additionally, the forming a low resistance contact layer 508 may include adding dopants. For example, the dopants may include Si, germanium, and/or other elements.

The forming a low resistance contact layer 508 may include utilizing a chamber, a vacuum chamber, a semiconductor processing chamber, a low-pressure structure, and/or the like that may include utilizing a plasma vapor for forming the low resistance contact layer 190. In aspects, the forming a low resistance contact layer 508 may utilize an inert gas and generate a plasma. In aspects, the inert gas may be nitrogen, argon, and/or any other type of noble gas.

Additionally, the forming a low resistance contact layer 508 may include etching and/or the like semiconductor processing techniques understood by those of ordinary skill in the art. In aspects, the forming a low resistance contact layer 508 may include an etch process to define a shape of the low resistance contact layer 190 on the upper barrier layer surface 208 and/or the upper channel layer surface 204 of the channel layer 104. In this regard, the etch process may include photo lithographic etching, etch back, patterning, and/or the like semiconductor processing techniques understood by those of ordinary skill in the art.

The process for implementing a transistor 500 of the disclosure may include forming a spacer layer 510. In this regard, the forming a spacer layer 510 may include any one or more materials, structures, arrangements, processes, and/or the like of the spacer layer 116 as described herein. Moreover, one or more proceeding or subsequent processes may also be implemented consistent with the disclosure.

The spacer layer 116 may be a passivation layer, such as SiN, AlO, SiO, SiO₂, AlN, or the like, or a combination incorporating multiple layers thereof, which may be deposited over the exposed surface of the barrier layer 108.

In one or more aspects, the source 110 may be formed and/or defined by an open area in the spacer layer 116 to the low resistance contact layer 190. The open area may be part of an ohmic window etch process. In this regard, the forming a spacer layer 510 may include modifying utilizing an ohmic window etching process. In this regard, the process may include etching through the spacer layer 116 to the low resistance contact layer 190.

In one or more aspects, the drain 112 may be formed and/or defined by an open area in the spacer layer 116 to the low resistance contact layer 190. The open area may be part of an ohmic window etch process. In this regard, the forming a spacer layer 510 may include modifying utilizing an ohmic window etching process. In this regard, the process may include etching through the spacer layer 116 to the low resistance contact layer 190.

The process for implementing a transistor 500 of the disclosure may include forming and arranging a source and a drain on the low resistance contact layer 512. In this regard, the forming and arranging a source and a drain on the low resistance contact layer 512 may include any one or more materials, structures, arrangements, processes, and/or the like of the source 110 and the drain 112 as described herein. Moreover, one or more proceeding or subsequent processes may also be implemented consistent with the disclosure.

The forming and arranging a source and a drain on the low resistance contact layer 512 may include utilizing a self-aligned ohmic evaporation process. More specifically, an evaporation of the ohmic metal contacts and a solvent-based liftoff. Accordingly, the source 110 and/or the drain 112 may be arranged and/or situated with respect to the low resistance contact layer 190 consistent with the disclosure as described herein.

The source 110 may be an ohmic contact of a suitable material that may be annealed. For example, the source 110 may be annealed at a temperature of from about 500° C. to about 800° C. for about 2 minutes. However, other times and temperatures may also be utilized. Times from about 30 seconds to about 10 minutes may be, for example, acceptable. In some aspects, the source 110 may include Al, Ti, Si, Ni, and/or Pt.

The process for implementing a transistor 500 of the disclosure may include additional processes 514. The additional processes 514 may include arranging the gate 114 on the barrier layer 108 between the source 110 and the drain 112. A layer of Ni, Pt, AU, or the like may be formed for the gate 114 by evaporative deposition or another technique. The gate structure may then be completed by deposition of Pt and Au, or other suitable materials. In some aspects, the contacts of the gate 114 may include Al, Ti, Si, Ni, and/or Pt.

The additional processes 514 may include forming the source contact 118 and the drain contact 122. In particular, nickel or another suitable material may be annealed to form an ohmic contact, for example. In some aspects, the contacts of the source contact 118 and the drain contact 122 may include Al, Ti, Si, Ni, and/or Pt. Such a deposition and annealing process may be carried out utilizing conventional techniques known to those of skill in the art. For example, an ohmic contact for the source contact 118 may be annealed at a temperature of from about 600° C. to about 1050° C.

The source 110 and the drain 112 electrodes may be formed making ohmic contacts such that an electric current flows between the source 110 and drain 112 electrodes via a two-dimensional electron gas (2DEG) induced at the heterointerface 152 between the channel layer 104 and barrier layer 108 when a gate 114 electrode is biased at an appropriate level. In one aspect, the heterointerface 152 may be in the range of 0.005 μm to 0.007 μm, 0.007 μm to 0.009 μm, and 0.009 μm to 0.011 μm.

The gate 114 may extend on top of a spacer or the spacer layer 116. The spacer layer 116 may be etched and the gate 114 deposited such that the bottom of the gate 114 is on the surface of barrier layer 108. The metal forming the gate 114 may be patterned to extend across spacer layer 116 so that the top of the gate 114 forms a field plate 132.

The additional processes 514 may include forming a field plate 132 that may be arranged on top of another spacer layer 117 that may be separated from the gate 114. In one aspect, the field plate 132 may be deposited on the spacer layer 117 between the gate 114 and the drain 112. In some aspects, the field plate 132 may include many different conductive materials with a suitable material being a metal, or combinations of metals, deposited using standard metallization methods. In one aspect, the field plate 132 may include titanium, gold, nickel, titanium/gold, nickel/gold, or the like. In one aspect, the connection 140 may be formed with the field plate 132 during the same manufacturing step. In one aspect, a plurality of the field plates 132 may be used. In one aspect, a plurality of the field plates 132 may be used and each of the plurality of field plates 132 may be stacked with a dielectric material therebetween. In one aspect, the field plate 132 extends toward the edge of gate 114 towards the drain 112. In one aspect, the field plate 132 extends towards the source 110. In one aspect, the field plate 132 extends towards the drain 112 and towards the source 110. In another aspect, the field plate 132 does not extend toward the edge of gate 114. Finally, the structure may be covered with a dielectric spacer layer such as silicon nitride. The dielectric spacer layer may also be implemented similar to the spacer layer 116. Moreover, it should be noted that the cross-sectional shape of the gate 114, shown in the Figures is exemplary. For example, the cross-sectional shape of the gate 114 in some aspects may not include the T-shaped extensions. Other constructions of the gate 114 may be utilized.

The additional processes 514 may include forming the connection 140 may be formed (see FIG. 7). In some aspects, the field plate 132 may be electrically connected to the source 110 with the connection 140. In one aspect, the connection 140 may be formed on the spacer layer 117 to extend between the field plate 132 and the source 110.

The following are a number of nonlimiting EXAMPLES of aspects of the disclosure.

One EXAMPLE: a transistor includes a group III-Nitride channel layer. The transistor also includes a group III-Nitride barrier layer on the group III-Nitride channel layer, the group III-Nitride barrier layer having a higher bandgap than a bandgap of the group III-Nitride channel layer. The transistor furthermore includes a low resistance contact layer on the group III-Nitride barrier layer and/or on the group III-Nitride channel layer. The transistor in addition includes a source electrically coupled to the group III-Nitride barrier layer. The transistor moreover includes a drain electrically coupled to the group III-Nitride barrier layer. The transistor also includes a gate on the group III-Nitride barrier layer. The transistor furthermore includes where at least one of the drain and the source are arranged on the low resistance contact layer.

The above-noted EXAMPLE may further include any one or a combination of more than one of the following EXAMPLES:

The transistor includes where the low resistance contact layer may include GaN. The transistor also includes where the low resistance contact layer may include n-type GaN. The transistor further includes where the low resistance contact layer may include a sputtered layer, a physical vapor deposited layer, a doped GaN film layer, and/or a n-type sputtered GaN layer. The transistor in addition includes where the low resistance contact layer may include a n-type sputtered GaN layer. The transistor moreover includes where the low resistance contact layer may include a sputtered layer, a layer formed by sputtering, a physical vapor deposited layer, a layer formed by physical vapor deposition, a doped GaN film layer, a n-type sputtered GaN layer, and/or a layer formed by sputtering n-type GaN. The transistor also includes where the low resistance contact layer is arranged on the group III-Nitride barrier layer with one or more intervening layers therebetween. The transistor further includes where the low resistance contact layer is arranged directly on the group III-Nitride barrier layer. The transistor in addition includes where the drain is arranged on the low resistance contact layer with one or more intervening layers therebetween. The transistor moreover includes where the drain is arranged directly on the low resistance contact layer. The transistor also includes where the source is arranged on the low resistance contact layer with one or more intervening layers therebetween. The transistor further includes where the source is arranged directly on the low resistance contact layer. The transistor in addition includes where the drain is arranged on the low resistance contact layer with one or more intervening layers therebetween; and where the source is arranged on the low resistance contact layer with one or more intervening layers therebetween. The transistor moreover includes where the drain is arranged directly on the low resistance contact layer; and where the source is arranged directly on the low resistance contact layer. The transistor also includes where the low resistance contact layer is configured to achieve very low contact resistance for the source and the drain. The transistor further includes where the low resistance contact layer is configured to improve a performance of the transistor. The transistor in addition includes where the low resistance contact layer is configured to improve a radiofrequency performance of the transistor. The transistor moreover includes where the group III-Nitride barrier layer includes an upper surface; and where the low resistance contact layer is structured and arranged to partially extend across the upper surface of the group III-Nitride barrier layer. The transistor also includes where the group III-Nitride barrier layer includes an upper surface; and where the low resistance contact layer is structured and arranged to partially extend across the upper surface of the group III-Nitride barrier layer below the source and the drain. The transistor also includes where the low resistance contact layer comprises a thickness of 10 nm-50 between an upper contact layer surface and a lower contact layer surface. The transistor further includes may include a field plate.

One EXAMPLE: a process includes providing a group III-Nitride channel layer. The process also includes providing a group III-Nitride barrier layer on the group III-Nitride channel layer, the group III-Nitride barrier layer having a higher bandgap than a bandgap of the group III-Nitride channel layer. The process furthermore includes providing a low resistance contact layer on the group III-Nitride barrier layer and/or on the group III-Nitride channel layer. The process in addition includes providing and electrically coupling a source to the group III-Nitride barrier layer. The process moreover includes providing and electrically coupling a drain to the group III-Nitride barrier layer. The process also includes providing a gate on the group III-Nitride barrier layer. The process furthermore includes where at least one of the drain and the source are arranged on the low resistance contact layer.

The above-noted EXAMPLE may further include any one or a combination of more than one of the following EXAMPLES:

The process includes where the low resistance contact layer may include GaN. The process also includes where the low resistance contact layer may include n-type GaN. The process further includes where the low resistance contact layer may include a sputtered layer, a physical vapor deposited layer, a doped GaN film layer, and/or a n-type sputtered GaN layer. The process in addition includes where the low resistance contact layer may include a n-type sputtered GaN layer. The process moreover includes may include forming the low resistance contact layer by sputtering n-type GaN. The process also includes may include forming the low resistance contact layer by physical vapor deposition. The process further includes where the low resistance contact layer may include a sputtered layer, a layer formed by sputtering, a physical vapor deposited layer, a layer formed by physical vapor deposition, a doped GaN film layer, a n-type sputtered GaN layer, and/or a layer formed by sputtering n-type GaN. The process in addition includes where the low resistance contact layer is arranged on the group III-Nitride barrier layer with one or more intervening layers therebetween. The process moreover includes where the low resistance contact layer is arranged directly on the group III-Nitride barrier layer. The process also includes where the drain is arranged on the low resistance contact layer with one or more intervening layers therebetween. The process further includes where the drain is arranged directly on the low resistance contact layer. The process in addition includes where the low resistance contact layer is arranged on the group III-Nitride barrier layer with one or more intervening layers therebetween; and where the drain is arranged on the low resistance contact layer with one or more intervening layers therebetween. The process moreover includes where the low resistance contact layer is arranged directly on the group III-Nitride barrier layer; and where the drain is arranged directly on the low resistance contact layer. The process also includes where the source is arranged on the low resistance contact layer with one or more intervening layers therebetween. The process further includes where the source is arranged directly on the low resistance contact layer. The process in addition includes where the low resistance contact layer is configured to achieve very low contact resistance for the source and the drain. The process moreover includes where the low resistance contact layer is configured to improve a performance of the transistor. The process also includes where the low resistance contact layer is configured to improve a radiofrequency performance of the transistor. The process further includes where the group III-Nitride barrier layer includes an upper surface; and where the low resistance contact layer is structured and arranged to extend across the upper surface of the group III-Nitride barrier layer. The process also includes where the low resistance contact layer comprises a thickness of 10 nm-50 between an upper contact layer surface and a lower contact layer surface. The process in addition includes may include forming a field plate.

One EXAMPLE: a transistor includes active semiconductor layers structured and arranged by a first deposition technique. The transistor also includes a low resistance contact layer structured and arranged by a second deposition technique on at least one of the active semiconductor layers. The transistor furthermore includes a source electrically coupled to at least one of the active semiconductor layers. The transistor in addition includes a drain electrically coupled to at least one of the active semiconductor layers. The transistor moreover includes a gate on at least one of the active semiconductor layers. The transistor also includes where at least one of the drain and the source are arranged on the low resistance contact layer. The transistor furthermore includes where the first deposition technique is different from the second deposition technique.

The above-noted EXAMPLE may further include any one or a combination of more than one of the following EXAMPLES:

The transistor includes where the first deposition technique may include chemical vapor deposition and/or Lateral Epitaxial Overgrowth (LEO); and where the second deposition technique may include non-epitaxial physical vapor deposition. The transistor also includes where the second deposition technique may include sputtering and/or physical vapor deposition. The transistor further includes where the low resistance contact layer may include GaN. The transistor in addition includes where the low resistance contact layer may include n-type GaN. The transistor moreover includes where the low resistance contact layer may include a sputtered layer, a physical vapor deposited layer, a doped GaN film layer, and/or a n-type sputtered GaN layer. The transistor also includes where the low resistance contact layer may include a n-type sputtered GaN layer. The transistor further includes where the low resistance contact layer may include a sputtered layer, a layer formed by sputtering, a physical vapor deposited layer, a layer formed by physical vapor deposition, a doped GaN film layer, a n-type sputtered GaN layer, and/or a layer formed by sputtering n-type GaN. The transistor in addition includes where at least one of the active semiconductor layers may include a group III-Nitride channel layer; where at least one of the active semiconductor layers may include a group III-Nitride barrier layer on the group III-Nitride channel layer; where the group III-Nitride barrier layer may include a higher bandgap than a bandgap of the group III-Nitride channel layer; where the low resistance contact layer is arranged on the group III-Nitride barrier layer and/or on the group III-Nitride channel layer; where the source electrically coupled to the group III-Nitride barrier layer; where the drain electrically coupled to the group III-Nitride barrier layer; where the gate on the group III-Nitride barrier layer; and where the low resistance contact layer is arranged on the group III-Nitride barrier layer with one or more intervening layers therebetween. The transistor moreover includes where at least one of the active semiconductor layers may include a group III-Nitride channel layer; where at least one of the active semiconductor layers may include a group III-Nitride barrier layer on the group III-Nitride channel layer; where the group III-Nitride barrier layer may include a higher bandgap than a bandgap of the group III-Nitride channel layer; where the low resistance contact layer is arranged on the group III-Nitride barrier layer and/or on the group III-Nitride channel layer; where the source electrically coupled to the group III-Nitride barrier layer; where the drain electrically coupled to the group III-Nitride barrier layer; where the gate on the group III-Nitride barrier layer; and where the low resistance contact layer is arranged directly on the group III-Nitride barrier layer. The transistor also includes where the drain is arranged on the low resistance contact layer with one or more intervening layers therebetween. The transistor further includes where the drain is arranged directly on the low resistance contact layer. The transistor in addition includes where the source is arranged on the low resistance contact layer with one or more intervening layers therebetween. The transistor moreover includes where the source is arranged directly on the low resistance contact layer. The transistor also includes where the drain is arranged on the low resistance contact layer with one or more intervening layers therebetween; and where the source is arranged on the low resistance contact layer with one or more intervening layers therebetween. The transistor further includes where the drain is arranged directly on the low resistance contact layer; and where the source is arranged directly on the low resistance contact layer. The transistor in addition includes where the low resistance contact layer is configured to achieve very low contact resistance for the source and the drain. The transistor moreover includes where the low resistance contact layer is configured to improve a performance of the transistor. The transistor also includes where the low resistance contact layer is configured to improve a radiofrequency performance of the transistor. The transistor further includes where at least one of the active semiconductor layers may include a group III-Nitride channel layer; where at least one of the active semiconductor layers may include a group III-Nitride barrier layer on the group III-Nitride channel layer; where the group III-Nitride barrier layer may include a higher bandgap than a bandgap of the group III-Nitride channel layer; where the low resistance contact layer is arranged on the group III-Nitride barrier layer and/or on the group III-Nitride channel layer; where the source electrically coupled to the group III-Nitride barrier layer; where the drain electrically coupled to the group III-Nitride barrier layer; where the gate on the group III-Nitride barrier layer; and where the group III-Nitride barrier layer includes an upper surface; and where the low resistance contact layer is structured and arranged to partially extend across the upper surface of the group III-Nitride barrier layer. The transistor in addition includes where at least one of the active semiconductor layers may include a group III-Nitride channel layer; where at least one of the active semiconductor layers may include a group III-Nitride barrier layer on the group III-Nitride channel layer; where the group III-Nitride barrier layer may include a higher bandgap than a bandgap of the group III-Nitride channel layer; where the low resistance contact layer is arranged on the group III-Nitride barrier layer and/or on the group III-Nitride channel layer; where the source electrically coupled to the group III-Nitride barrier layer; where the drain electrically coupled to the group III-Nitride barrier layer; where the gate on the group III-Nitride barrier layer; and where the group III-Nitride barrier layer includes an upper surface; and where the low resistance contact layer is structured and arranged to partially extend across the upper surface of the group III-Nitride barrier layer below the source and the drain. The transistor also includes where the low resistance contact layer comprises a thickness of 10 nm-50 between an upper contact layer surface and a lower contact layer surface. The transistor moreover includes may include a field plate.

One EXAMPLE: a process includes providing active semiconductor layers structured and arranged by a first deposition technique. The process also includes providing a low resistance contact layer structured and arranged by a second deposition technique on at least one of the active semiconductor layers. The process furthermore includes providing a source electrically coupled to at least one of the active semiconductor layers. The process in addition includes providing a drain electrically coupled to at least one of the active semiconductor layers. The process moreover includes providing a gate on at least one of the active semiconductor layers. The process also includes where at least one of the drain and the source are arranged on the low resistance contact layer. The process furthermore includes where the first deposition technique is different from the second deposition technique.

The above-noted EXAMPLE may further include any one or a combination of more than one of the following EXAMPLES:

The process includes where the first deposition technique may include chemical vapor deposition and/or Lateral Epitaxial Overgrowth (LEO); and where the second deposition technique may include non-epitaxial physical vapor deposition. The process also includes where the second deposition technique may include sputtering and/or physical vapor deposition. The process further includes where the low resistance contact layer may include GaN. The process in addition includes where the low resistance contact layer may include n-type GaN. The process moreover includes where the low resistance contact layer may include a sputtered layer, a physical vapor deposited layer, a doped GaN film layer, and/or a n-type sputtered GaN layer. The process also includes where the low resistance contact layer may include a n-type sputtered GaN layer. The process further includes may include forming the low resistance contact layer by sputtering n-type GaN. The process in addition includes may include forming the low resistance contact layer by physical vapor deposition. The process moreover includes where the low resistance contact layer may include a sputtered layer, a layer formed by sputtering, a physical vapor deposited layer, a layer formed by physical vapor deposition, a doped GaN film layer, a n-type sputtered GaN layer, and/or a layer formed by sputtering n-type GaN. The process also includes where at least one of the active semiconductor layers may include a group III-Nitride channel layer; where at least one of the active semiconductor layers may include a group III-Nitride barrier layer on the group III-Nitride channel layer; where the group III-Nitride barrier layer may include a higher bandgap than a bandgap of the group III-Nitride channel layer; where the low resistance contact layer is arranged on the group III-Nitride barrier layer and/or on the group III-Nitride channel layer; where the source electrically coupled to the group III-Nitride barrier layer; where the drain electrically coupled to the group III-Nitride barrier layer; where the gate on the group III-Nitride barrier layer; and where the low resistance contact layer is arranged on the group III-Nitride barrier layer with one or more intervening layers therebetween. The process further includes where at least one of the active semiconductor layers may include a group III-Nitride channel layer; where at least one of the active semiconductor layers may include a group III-Nitride barrier layer on the group III-Nitride channel layer; where the group III-Nitride barrier layer may include a higher bandgap than a bandgap of the group III-Nitride channel layer; where the low resistance contact layer is arranged on the group III-Nitride barrier layer and/or on the group III-Nitride channel layer; where the source electrically coupled to the group III-Nitride barrier layer; where the drain electrically coupled to the group III-Nitride barrier layer; where the gate on the group III-Nitride barrier layer; and where the low resistance contact layer is arranged directly on the group III-Nitride barrier layer. The process in addition includes where the drain is arranged on the low resistance contact layer with one or more intervening layers therebetween. The process moreover includes where the drain is arranged directly on the low resistance contact layer. The process also includes where at least one of the active semiconductor layers may include a group III-Nitride channel layer; where at least one of the active semiconductor layers may include a group III-Nitride barrier layer on the group III-Nitride channel layer; where the group III-Nitride barrier layer may include a higher bandgap than a bandgap of the group III-Nitride channel layer; where the low resistance contact layer is arranged on the group III-Nitride barrier layer and/or on the group III-Nitride channel layer; where the source electrically coupled to the group III-Nitride barrier layer; where the drain electrically coupled to the group III-Nitride barrier layer; where the gate on the group III-Nitride barrier layer; where the low resistance contact layer is arranged on the group III-Nitride barrier layer with one or more intervening layers therebetween; and where the drain is arranged on the low resistance contact layer with one or more intervening layers therebetween. The process further includes where at least one of the active semiconductor layers may include a group III-Nitride channel layer; where at least one of the active semiconductor layers may include a group III-Nitride barrier layer on the group III-Nitride channel layer; where the group III-Nitride barrier layer may include a higher bandgap than a bandgap of the group III-Nitride channel layer; where the low resistance contact layer is arranged on the group III-Nitride barrier layer and/or on the group III-Nitride channel layer; where the source electrically coupled to the group III-Nitride barrier layer; where the drain electrically coupled to the group III-Nitride barrier layer; where the gate on the group III-Nitride barrier layer; where the low resistance contact layer is arranged directly on the group III-Nitride barrier layer; and where the drain is arranged directly on the low resistance contact layer. The process in addition includes where the source is arranged on the low resistance contact layer with one or more intervening layers therebetween. The process moreover includes where the source is arranged directly on the low resistance contact layer. The process also includes where the low resistance contact layer is configured to achieve very low contact resistance for the source and the drain. The process further includes where the low resistance contact layer is configured to improve a performance of the transistor. The process in addition includes where the low resistance contact layer is configured to improve a radiofrequency performance of the transistor. The process moreover includes where at least one of the active semiconductor layers may include a group III-Nitride channel layer; where at least one of the active semiconductor layers may include a group III-Nitride barrier layer on the group III-Nitride channel layer; where the group III-Nitride barrier layer may include a higher bandgap than a bandgap of the group III-Nitride channel layer; where the low resistance contact layer is arranged on the group III-Nitride barrier layer and/or on the group III-Nitride channel layer; where the source electrically coupled to the group III-Nitride barrier layer; where the drain electrically coupled to the group III-Nitride barrier layer; where the gate on the group III-Nitride barrier layer; where the group III-Nitride barrier layer includes an upper surface; and where the low resistance contact layer is structured and arranged to extend across the upper surface of the group III-Nitride barrier layer. The process also includes where the low resistance contact layer comprises a thickness of 10 nm-50 between an upper contact layer surface and a lower contact layer surface. The process also includes may include forming a field plate.

Accordingly, the disclosure has provided structures and processes for low resistance ohmic contacts in transistors. In particular, the disclosure has provided structures and processes for low resistance ohmic contacts in Group-III nitride HEMTs.

Aluminum indium gallium nitride (often written as AlₓIn_{y}Ga_{z}N where 0≤x≤1, 0≤y≤1, 0≤z≤1, and x+y+z=1, or (AlInGa) N or AlInGaN or sometimes simply GaN) is an alloy that is increasingly used for power switching, amplification and other applications. Given the material properties of AlInGaN, semiconductor devices made from this material can operate at higher voltages, higher temperatures, higher switching frequencies, with lower on resistance and ultimately achieving greater system efficiencies, e.g., when compared to existing Si devices. These properties can enable significantly reduced system volume due to decreased cooling requirements and smaller passive components, thus contributing to overall lower system costs, e.g. when compared to silicon. Power devices made from GaN and its alloys show great promise for applications including power conversion, power control, power conditioning, power switching, or power management. In particular, power supplies, motor drives, photovoltaic inverters, UPS inverters, EV chargers and EV/HEC converter/inverter/drives will benefit from the improved efficiency, speed and size of “GaN Power” devices. In this regard, the transistor 100 may be implemented as a “GaN Power” device.

According to further aspects of this disclosure, transistors, such as GaN HEMTs, fabricated on high resistivity substrates may be utilized for high power RF (radio frequency) amplifiers, for high power radiofrequency (RF) applications, and also for low frequency high power switching applications. The advantageous electronic and thermal properties of GaN HEMTs also make them very attractive for switching high power RF signals. In this regard, the disclosure has described a structure with a buried p-layer under the source region to obtain high breakdown voltage in HEMTs for various applications including power amplifiers while at the same time eliminating drifts in device characteristics arising from trapping in the buffer and/or semi-insulating substrates. Use of buried p-layers may also be important in HEMTs for RF switches to obtain high breakdown voltage and good isolation between the input and output.

In particular aspects, the transistor 100 of the disclosure may be utilized in wireless base stations that connect to a wireless device. In further aspects, the transistor 100 of the disclosure may be utilized in amplifiers implemented by wireless base stations that connect to a wireless device. In further aspects, the transistor 100 of the disclosure may be utilized in wireless devices. In further aspects, the transistor 100 of the disclosure may be utilized in amplifiers implemented in wireless devices.

In this disclosure it is to be understood that reference to a wireless device is intended to encompass electronic devices such as mobile phones, tablet computers, gaming systems, MP3 players, personal computers, PDAs, user equipment (UE), and the like. A “wireless device” is intended to encompass any compatible mobile technology computing device that can connect to a wireless communication network, such as mobile phones, mobile equipment, mobile stations, user equipment, cellular phones, smartphones, handsets, wireless dongles, remote alert devices, Internet of things (IoT) based wireless devices, or other mobile computing devices that may be supported by a wireless network. The wireless device may utilize wireless communication technologies like GSM, CDMA, wireless local loop, Wi-Fi, WiMAX, other wide area network (WAN) technology, 3G technology, 4G technology, 5G technology, LTE technology, and/or the like.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure.

1. A transistor comprising:
a group III-Nitride channel layer;
a group III-Nitride barrier layer on the group III-Nitride channel layer, the group III-Nitride barrier layer comprising a higher bandgap than a bandgap of the group III-Nitride channel layer;
a low resistance contact layer on the group III-Nitride barrier layer and/or on the group III-Nitride channel layer;
a source electrically coupled to the group III-Nitride barrier layer;
a drain electrically coupled to the group III-Nitride barrier layer; and
a gate on the group III-Nitride barrier layer,
wherein at least one of the drain and the source are arranged on the low resistance contact layer.

2. The transistor of claim 1, wherein the low resistance contact layer comprises GaN.

3. The transistor of claim 1, wherein the low resistance contact layer comprises n-type GaN.

4. The transistor of claim 1, wherein the low resistance contact layer comprises a sputtered layer, a physical vapor deposited layer, a doped GaN film layer, and/or a n-type sputtered GaN layer.

5. The transistor of claim 1, wherein the low resistance contact layer comprises a n-type sputtered GaN layer.

6. The transistor of claim 1, wherein the low resistance contact layer comprises a sputtered layer, a layer formed by sputtering, a physical vapor deposited layer, a layer formed by physical vapor deposition, a doped GaN film layer, a n-type sputtered GaN layer, and/or a layer formed by sputtering n-type GaN.

7.-8. (canceled)

9. The transistor of claim 1, wherein the drain is arranged on the low resistance contact layer with one or more intervening layers therebetween.

10. (canceled)

11. The transistor of claim 1, wherein the source is arranged on the low resistance contact layer with one or more intervening layers therebetween.

12.-15. (canceled)

16. The transistor of claim 1, wherein the low resistance contact layer is configured to improve a performance of the transistor.

17. The transistor of claim 1, wherein the low resistance contact layer is configured to improve a radiofrequency performance of the transistor.

18.-20. (canceled)

21. The transistor of claim 1, further comprising a field plate.

22. A process of implementing a transistor comprising:
providing a group III-Nitride channel layer;
providing a group III-Nitride barrier layer on the group III-Nitride channel layer, the group III-Nitride barrier layer comprising a higher bandgap than a bandgap of the group III-Nitride channel layer;
providing a low resistance contact layer on the group III-Nitride barrier layer and/or on the group III-Nitride channel layer;
providing and electrically coupling a source to the group III-Nitride barrier layer;
providing and electrically coupling a drain to the group III-Nitride barrier layer; and
providing a gate on the group III-Nitride barrier layer,
wherein at least one of the drain and the source are arranged on the low resistance contact layer.

23.-26. (canceled)

27. The process of implementing a transistor of claim 22, further comprising forming the low resistance contact layer by sputtering n-type GaN.

28.-43. (canceled)

44. A transistor comprising:
active semiconductor layers structured and arranged by a first deposition technique;
a low resistance contact layer structured and arranged by a second deposition technique on at least one of the active semiconductor layers;
a source electrically coupled to at least one of the active semiconductor layers;
a drain electrically coupled to at least one of the active semiconductor layers; and
a gate on at least one of the active semiconductor layers,
wherein at least one of the drain and the source are arranged on the low resistance contact layer; and
wherein the first deposition technique is different from the second deposition technique.

45. The transistor of claim 44
wherein the first deposition technique comprises chemical vapor deposition and/or Lateral Epitaxial Overgrowth (LEO); and
wherein the second deposition technique comprises non-epitaxial physical vapor deposition.

46. The transistor of claim 44 wherein the second deposition technique comprises sputtering and/or physical vapor deposition.

47. The transistor of claim 44, wherein the low resistance contact layer comprises GaN.

48. The transistor of claim 44, wherein the low resistance contact layer comprises n-type GaN.

49. The transistor of claim 44, wherein the low resistance contact layer comprises a sputtered layer, a physical vapor deposited layer, a doped GaN film layer, and/or a n-type sputtered GaN layer.

50.-51. (canceled)

52. The transistor of claim 44,
wherein at least one of the active semiconductor layers comprises a group III-Nitride channel layer;
wherein at least one of the active semiconductor layers comprises a group III-Nitride barrier layer on the group III-Nitride channel layer;
wherein the group III-Nitride barrier layer comprises a higher bandgap than a bandgap of the group III-Nitride channel layer;
wherein the low resistance contact layer is arranged on the group III-Nitride barrier layer and/or on the group III-Nitride channel layer;
wherein the source electrically coupled to the group III-Nitride barrier layer;
wherein the drain electrically coupled to the group III-Nitride barrier layer;
wherein the gate on the group III-Nitride barrier layer; and
wherein the low resistance contact layer is arranged on the group III-Nitride barrier layer with one or more intervening layers therebetween.

53.-90. (canceled)
